(19) United States
(12) Patent Application Publication
(10) Pub. No.: US 2025/0275374 A1
(43) Pub. Date: Aug. 28, 2025

(54) DISPLAY DEVICE

(71) Applicant: Samsung Display Co., LTD., Yongin-si (KR)

(72) Inventors: Da Sol JEONG, Yongin-si (KR); Dong Gyun KIM, Yongin-si (KR); Tae Seop KIM, Yongin-si (KR); Young Deok SEO, Yongin-si (KR); Dae Ho SONG, Yongin-si (KR); Eun Ho SONG, Yongin-si (KR); Seok Hyun LIM, Yongin-si (KR); Seung Hwan CHO, Yongin-si (KR)

(21) Appl. No.: 18/968,925

(22) Filed: Dec. 4, 2024

(30) Foreign Application Priority Data
Feb. 27, 2024 (KR) 10-2024-0027993

(51) Int. Cl. H10K 59/122; H10K 59/80

(52) U.S. Cl. CPC H10K 59/122; H10K 59/80516; H10K 59/80518

(57) ABSTRACT

A display device includes a substrate, a first insulating layer above the substrate, a first electrode above the first insulating layer, a second insulating layer above the first insulating layer and the first electrode along a curve of the first insulating layer and the first electrode, a second electrode above the second insulating layer, a light-emitting structure above the second electrode, and a third electrode above the light-emitting structure.

### CROSS-REFERENCE TO RELATED APPLICATION

This application claims priority to, and the benefit of, Korean Patent Application No. 10-2024-0027993, filed on Feb. 27, 2024, the entire disclosure of which is herein incorporated by reference.

### BACKGROUND

### 1. Field

The disclosure relates to a display device and a method of manufacturing the same.

### 2. Description of the Related Art

As information technology develops, importance of a display device, which is a connection medium between a user and information, is emerging. In response to this, a use of a display device, such as a liquid crystal display device and an organic light-emitting display device is increasing.

Recently, a head-mounted display device (HMD) is being developed. The HMD is a display device that implements virtual reality (VR) or augmented reality (AR), in which a user wears the HMD in a form of glasses or a helmet, and in which a focus is formed at a distance relatively close to eyes. A high-resolution panel is applied to the HMD, and thus a pixel that may be applied to the high-resolution panel is suitable.

### SUMMARY

The disclosure provides a display device of which a process is simplified, and a method of manufacturing a display device.

According to embodiments of the disclosure, a display device includes a substrate, a first insulating layer above the substrate, a first electrode above the first insulating layer, a second insulating layer above the first insulating layer and the first electrode along a curve of the first insulating layer and the first electrode, a second electrode above the second insulating layer, a light-emitting structure above the second electrode, and a third electrode above the light-emitting structure.

The second insulating layer may define a first opening exposing at least a portion of the first electrode, wherein the second electrode directly contacts the first electrode.

The display device may further include a third insulating layer defining a second opening exposing at least a portion of the second electrode, wherein the third insulating layer is above an area of the second electrode that directly contacts the first electrode.

The substrate may include a display area where first, second, and third sub-pixels are located, wherein respective thicknesses of the second insulating layer above respective portions of the first electrode in at least two of the first, second, or third sub-pixels are different.

The second insulating layer may include a (2-1)-th insulating layer and a (2-2)-th insulating layer, wherein a portion of the (2-1)-th insulating layer or a portion of the (2-2)-th insulating layer is omitted above a portion of the first electrode.

The display device may further include a third insulating layer defining a second opening exposing at least a portion of the second electrode, and a sacrificial layer between the second electrode and the third insulating layer.

The sacrificial layer may include a conductive material.

The sacrificial layer may have an under-cut structure between the second electrode and the third insulating layer.

The light-emitting structure may be configured to output white light.

According to embodiments of the disclosure, a display device includes a substrate, a first insulating layer above the substrate, a first electrode above the first insulating layer, a second insulating layer above the first insulating layer and the first electrode, and directly contacting the first electrode, a second electrode above the second insulating layer, a light-emitting structure above the second electrode, and a third electrode above the light-emitting structure.

The display device may further include a third insulating layer defining a second opening exposing at least a portion of the second electrode, wherein the third insulating layer is above an area of the second electrode that directly contacts the first electrode.

The substrate may include a display area where first, second, and third sub-pixels are located, wherein respective thicknesses of the second insulating layer above respective portions of the first electrode in at least two of the first, second, or third sub-pixels are different.

The second insulating layer may include a (2-1)-th insulating layer and a (2-2)-th insulating layer, wherein a portion of the (2-1)-th insulating layer or a portion of the (2-2)-th insulating layer is omitted above a portion of the first electrode.

The display device may further include a third insulating layer defining a second opening exposing at least a portion of the second electrode, and a sacrificial layer between the second electrode and the third insulating layer.

The sacrificial layer may include a conductive material.

The sacrificial layer may have an under-cut structure between the second electrode and the third insulating layer.

The light-emitting structure may be configured to output white light.

A display device according to embodiments of the disclosure may simplify a manufacturing process by omitting a planarization process of a differential layer.

A display device according to embodiments of the disclosure may simplify a manufacturing process by directly connecting an anode electrode to a reflective electrode without passing through a via.

A display device according to embodiments of the disclosure may protect an anode electrode by including a sacrificial layer.

However, the disclosure is not limited to the above, and may be variously expanded without departing from the spirit and scope of the disclosure.

### BRIEF DESCRIPTION OF THE DRAWINGS

The above and other aspects of the disclosure will become more apparent by describing in further detail embodiments thereof with reference to the accompanying drawings, in which:

FIG. 1 is a block diagram illustrating one or more embodiments of a display device;

FIG. 2 is a block diagram illustrating one or more embodiments of one of sub-pixels of FIG. 1;

FIG. 3 is a plan view illustrating one or more embodiments of a display panel of FIG. 1;

FIG. 4 is an exploded perspective view illustrating a portion of the display panel of FIG. 3;

FIG. 5 is a plan view illustrating one or more embodiments of one of the pixels of FIG. 4;

FIG. 6 is a cross-sectional view taken along the line I-I′ of FIG. 5;

FIG. 7 is a table illustrating examples of a thickness of a differential layer of FIG. 6;

FIG. 8 is a cross-sectional view illustrating CASE6 of FIG. 7;

FIG. 9 is a cross-sectional view illustrating one or more embodiments of a light-emitting structure included in one of first to third light-emitting elements of FIG. 6;

FIG. 10 is a cross-sectional view illustrating one or more other embodiments of the light-emitting structure included in one of the first to third light-emitting elements of FIG. 6;

FIG. 11 is a cross-sectional view illustrating still one or more other embodiments of the light-emitting structure included in one of the first to third light-emitting elements of FIG. 6;

FIG. 12 is a plan view illustrating one or more other embodiments of one of the pixels of FIG. 4;

FIG. 13 is a plan view illustrating still one or more other embodiments of one of the pixels of FIG. 4;

FIGS. 14 to 16 are cross-sectional views illustrating an example of a shape of a first lens of FIG. 6;

FIG. 17 is a cross-sectional view illustrating a portion of first to third sub-pixels of a display device according to embodiments of the disclosure;

FIG. 18 is a flowchart illustrating a method of manufacturing a display device according to embodiments of the disclosure;

FIG. 19 is a diagram illustrating operation S200 of FIG. 18;

FIG. 20 is a diagram illustrating operation S300 of FIG. 18;

FIG. 21 is a diagram illustrating operation S400 of FIG. 18;

FIG. 22 is a diagram illustrating operation S500 of FIG. 18;

FIG. 23 is a diagram illustrating operation S600 of FIG. 18;

FIGS. 24 to 28 are diagrams illustrating a process in which a first differential layer and a second differential layer are formed according to a method of manufacturing a display device according to embodiments of the disclosure;

FIGS. 29 to 31 are diagrams illustrating a process in which a sacrificial layer is formed according to a method of manufacturing a display device according to embodiments of the disclosure;

FIG. 32 is a block diagram illustrating one or more embodiments of a display system;

FIG. 33 is a perspective view illustrating an application example of the display system of FIG. 32; and

FIG. 34 is a diagram illustrating the head-mounted display device worn by a user of FIG. 33.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure.

A person of ordinary skill in the art would appreciate, in view of the present disclosure in its entirety, that the present disclosure covers all modifications, equivalents, and replacements within the idea and technical scope of the present disclosure, that each of the features of embodiments of the present disclosure may be combined with each other, in part or in whole, and technically various interlocking and operating are possible, and that each embodiment may be implemented independently of each other, or may be implemented together in an association, unless otherwise stated or implied.

In the drawings, the relative sizes of elements, layers, and regions may be exaggerated for clarity and/or descriptive purposes. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “over,” “higher,” “upper side,” “side” (e.g., as in “sidewall”), and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component is referred to as being “formed on,” “on,” “connected to,” or “(operatively or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a resistor, a capacitor, and/or the like. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XYY, YZ, and ZZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list. When “C to D” is stated, it means C or more and D or less, unless otherwise specified.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are only used to distinguish one element, member, component, region, area, layer, section, or portion from another element, member, component, region, area, layer, section, or portion. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

When one or more embodiments may be implemented differently, a specific process order may be performed differently from the described order. For example, two consecutively described processes may be performed substantially at the same time or performed in an order opposite to the described order.

As used herein, the terms “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/−5% of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.”

In some embodiments well-known structures and devices may be described in the accompanying drawings in relation to one or more functional blocks (e.g., block diagrams), units, and/or modules to avoid unnecessarily obscuring various embodiments. Those skilled in the art will understand that such block, unit, and/or module are/is physically implemented by a logic circuit, an individual component, a microprocessor, a hard wire circuit, a memory element, a line connection, and other electronic circuits. This may be formed using a semiconductor-based manufacturing technique or other manufacturing techniques. The block, unit, and/or module implemented by a microprocessor or other similar hardware may be programmed and controlled using software to perform various functions discussed herein, optionally may be driven by firmware and/or software. In addition, each block, unit, and/or module may be implemented by dedicated hardware, or a combination of dedicated hardware that performs some functions and a processor (for example, one or more programmed microprocessors and related circuits) that performs a function different from those of the dedicated hardware. In addition, in some embodiments, the block, unit, and/or module may be physically separated into two or more interact individual blocks, units, and/or modules without departing from the scope of the present disclosure. In addition, in some embodiments, the block, unit and/or module may be physically combined into more complex blocks, units, and/or modules without departing from the scope of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

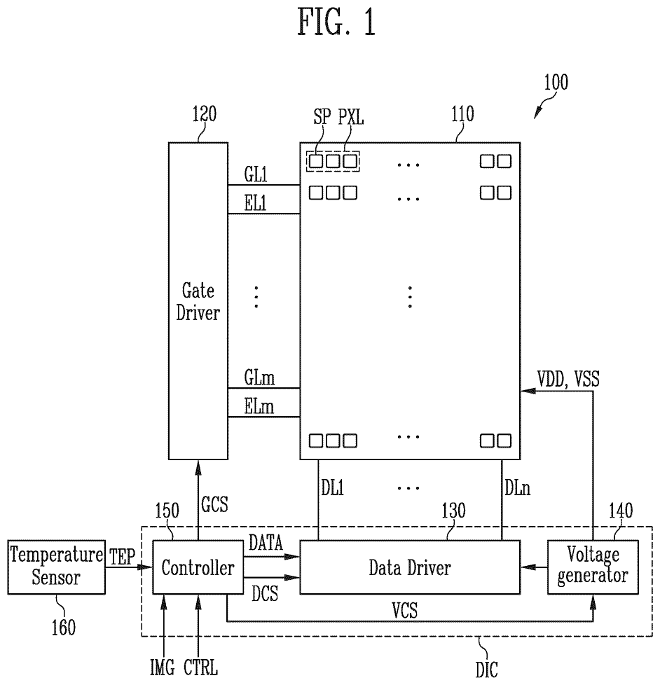

FIG. 1 is a block diagram illustrating one or more embodiments of a display device.

Referring to FIG. 1, the display device 100 may include a display panel 110, a gate driver 120, a data driver 130, a voltage generator 140, and a controller 150.

The display panel 110 includes sub-pixels SP. The sub-pixels SP may be connected to the gate driver 120 through first to m-th gate lines GL1 to GLm. The sub-pixels SP may be connected to the data driver 130 through first to n-th data lines DL1 to DLn.

Each of the sub-pixels SP may include at least one light-emitting element configured to generate light. Accordingly, each of the sub-pixels SP may generate light of a corresponding color, such as red, green, blue, cyan, magenta, or yellow. Two or more sub-pixels among the sub-pixels SP may configure one pixel PXL. For example, as shown in FIG. 1, three sub-pixels SP may configure one pixel PXL.

The gate driver 120 is connected to the sub-pixels SP arranged in a row direction through the first to m-th gate lines GL1 to GLm. The gate driver 120 may output gate signals to the first to m-th gate lines GL1 to GLm in response to a gate control signal GCS. In embodiments, the gate control signal GCS may include a start signal indicating a start of each frame, a horizontal synchronization signal for outputting the gate signals in synchronization with a timing at which data signals are applied, and the like.

In embodiments, first to m-th emission control lines EL1 to ELm connected to the sub-pixels SP of the row direction may be further provided. In this case, the gate driver 120 may include an emission control driver configured to control the first to m-th emission control lines EL1 to ELm, and the emission control driver may operate under control of the controller 150.

The gate driver 120 may be located on one side of the display panel 110. However, embodiments are not limited thereto. For example, the gate driver 120 may be divided into two or more physically and/or logically divided drivers, and such drivers may be respectively located on one side of the display panel 110 and another side of the display panel 110 that is opposite the one side. As described above, the gate driver 120 may be located around the display panel 110 in various shapes according to embodiments.

The data driver 130 is connected to the sub-pixels SP arranged in a column direction through the first to n-th data lines DL1 to DLn. The data driver 130 receives image data DATA and a data control signal DCS from the controller 150. The data driver 130 operates in response to the data control signal DCS. In embodiments, the data control signal DCS may include a source start pulse, a source shift clock, a source output enable signal, and the like.

The data driver 130 may apply data signals having grayscale voltages corresponding to the image data DATA to the first to n-th data lines DL1 to DLn using voltages from the voltage generator 140. When the gate signal is applied to each of the first to m-th gate lines GL1 to GLm, the data signals corresponding to the image data DATA may be applied to the data lines DL1 to DLn. Accordingly, the corresponding sub-pixels SP may generate light corresponding to the data signals. Accordingly, an image is displayed on the display panel 110.

In embodiments, the gate driver 120 and the data driver 130 may include complementary metal-oxide semiconductor (CMOS) circuit elements.

The voltage generator 140 may operate in response to a voltage control signal VCS from the controller 150. The voltage generator 140 is configured to generate a plurality of voltages, and to provide the generated voltages to components of the display device 100. For example, the voltage generator 140 may be configured to generate the plurality of voltages by receiving an input voltage from an outside of the display device 100, by adjusting the received voltage, and by regulating the adjusted voltage.

The voltage generator 140 may generate a first power voltage VDD and a second power voltage VSS, and the generated first and second power voltages VDD and VSS may be provided to the sub-pixels SP. The first power voltage VDD may have a relatively high voltage level, and the second power voltage VSS may have a voltage level that is lower than that of the first power voltage VDD. In other embodiments, the first power voltage VDD or the second power voltage VSS may be provided by an external device of the display device 100.

In addition, the voltage generator 140 may generate various voltages. For example, the voltage generator 140 may generate an initialization voltage applied to the sub-pixels SP. For example, during a sensing operation for sensing electrical characteristics of transistors and/or light-emitting elements of the sub-pixels SP, a reference voltage (e.g., predetermined reference voltage) may be applied to the first to n-th data lines DL1 to DLn, and the voltage generator 140 may generate such a reference voltage.

The controller 150 controls overall operations of the display device 100. The controller 150 receives input image data IMG and a control signal CTRL for controlling display of the input image data IMG from the outside. The controller 150 may provide the gate control signal GCS, the data control signal DCS, and the voltage control signal VCS in response to the control signal CTRL.

The controller 150 may convert the input image data IMG so that the input image data IMG is suitable for the display device 100 or the display panel 110 and output the image data DATA. In embodiments, the controller 150 may output the image data DATA by aligning the input image data IMG so that the input image data IMG is suitable for the sub-pixels SP of a row unit.

Two or more components of the data driver 130, the voltage generator 140, or the controller 150 may be mounted on one integrated circuit. As shown in FIG. 1, the data driver 130, the voltage generator 140, and the controller 150 may be included in a driver integrated circuit DIC. In this case, the data driver 130, the voltage generator 140, and the controller 150 may be functionally divided components in one driver integrated circuit DIC. In other embodiments, at least one of the data driver 130, the voltage generator 140, or the controller 150 may be provided as a component distinguished from the driver integrated circuit DIC.

The display device 100 may include at least one temperature sensor 160. The temperature sensor 160 is configured to sense a temperature around the temperature sensor 160, and to generate temperature data TEP indicating the sensed temperature. In embodiments, the temperature sensor 160 may be located adjacent to the display panel 110 and/or the driver integrated circuit DIC.

The controller 150 may control various operations of the display device 100 in response to the temperature data TEP. In embodiments, the controller 150 may adjust a luminance of the image output from the display panel 110 in response to the temperature data TEP. For example, the controller 150 may control the data signals and the first and second power voltages VDD and VSS by controlling components, such as the data driver 130 and/or the voltage generator 140.

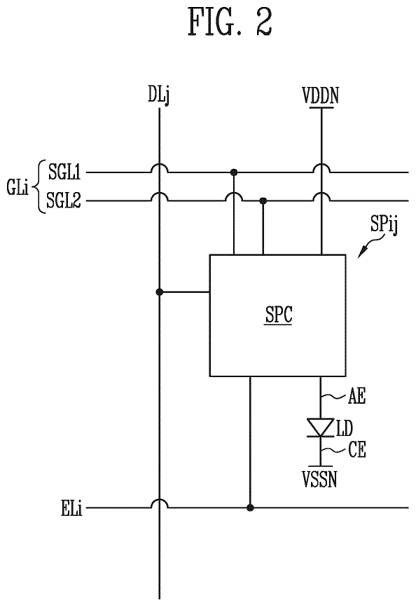

FIG. 2 is a block diagram illustrating one or more embodiments of one of the sub-pixels of FIG. 1. In FIG. 2, among the sub-pixels SP of FIG. 1, a sub-pixel SPij arranged in an i-th row (i is an integer greater than or equal to 1 and less than or equal to m) and a j-th column (j is an integer greater than or equal to 1 and less than or equal to n) is shown as an example.

Referring to FIG. 2, the sub-pixel SPij may include a sub-pixel circuit SPC and a light-emitting element LD.

The light-emitting element LD is connected between a first power voltage node VDDN and a second power voltage node VSSN. At this time, the first power voltage node VDDN is a node that transfers the first power voltage VDD of FIG. 1, and the second power voltage node VSSN is a node that transfers the second power voltage VSS of FIG. 1.

An anode electrode (e.g., a second electrode) AE of the light-emitting element LD may be connected to the first power voltage node VDDN through the sub-pixel circuit SPC, and a cathode electrode (e.g., a third electrode) CE of the light-emitting element LD may be connected to the second power voltage node VSSN. For example, the anode electrode AE of the light-emitting element LD may be connected to the first power voltage node VDDN through one or more transistors included in the sub-pixel circuit SPC.

The sub-pixel circuit SPC may be connected to an i-th gate line GLi among the first to m-th gate lines GL1 to GLm of FIG. 1, an i-th emission control line ELi among the first to m-th emission control lines EL1 to ELm of FIG. 1, and a j-th data line DLj among the first to n-th data lines DL1 to DLn of FIG. 1. The sub-pixel circuit SPC is configured to control the light-emitting element LD according to signals received through such signal lines.

The sub-pixel circuit SPC may operate in response to a gate signal received through the i-th gate line GLi. The i-th gate line GLi may include one or more sub-gate lines. In embodiments, as shown in FIG. 2, the i-th gate line GLi may include first and second sub-gate lines SGL1 and SGL2. The sub-pixel circuit SPC may operate in response to gate signals received through the first and second sub-gate lines SGL1 and SGL2. As described above, when the i-th gate line GLi includes two or more sub-gate lines, the sub-pixel circuit SPC may operate in response to gate signals received through the corresponding sub-gate lines.

The sub-pixel circuit SPC may operate in response to an emission control signal received through the i-th emission control line ELi. In embodiments, the i-th emission control line ELi may include one or more sub-emission control lines. When the i-th emission control line ELi includes two or more sub-emission control lines, the sub-pixel circuit SPC may operate in response to emission control signals received through the corresponding sub-emission control lines.

The sub-pixel circuit SPC may receive a data signal through the j-th data line DLj. The sub-pixel circuit SPC may store a voltage corresponding to the data signal in response to at least one of the gate signals received through the first and second sub-gate lines SGL1 and SGL2. The sub-pixel circuit SPC may adjust a current flowing from the first power voltage node VDDN to the second power voltage node VSSN through the light-emitting element LD according to the stored voltage, in response the emission control signal received through the i-th emission control line ELi. Accordingly, the light-emitting element LD may generate light of a luminance corresponding to the data signal.

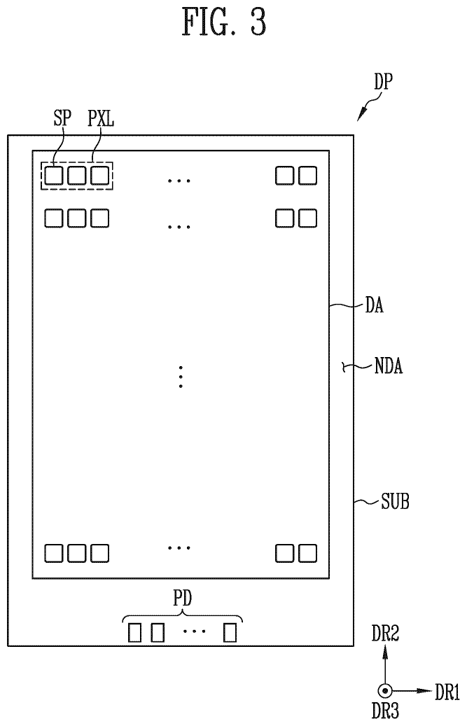

FIG. 3 is a plan view illustrating one or more embodiments of the display panel of FIG. 1.

Referring to FIG. 3, one or more embodiments DP of the display panel 110 of FIG. 1 may include a display area DA and a non-display area NDA. The display panel DP displays an image through the display area DA. The non-display area NDA is located around the display area DA.

The display panel DP may include a substrate SUB, the sub-pixels SP, and pads PD.

When the display panel DP is used as a display screen of a head-mounted display (HMD), a virtual reality (VR) device, a mixed reality (MR) device, an augmented reality (AR) device, or the like, the display panel DP may be positioned very close to user's eyes. In this case, sub-pixels SP of a relatively high integration degree are suitable. To increase an integration degree of the sub-pixels SP, the substrate SUB may be provided as a silicon substrate. The sub-pixels SP and/or the display panel DP may be formed on the substrate SUB, which is the silicon substrate. The display device 100 (refer to FIG. 1) including the display panel DP formed on the substrate SUB, which is the silicon substrate, may be referred to as an OLED on silicon (OLEDoS) display device.

The sub-pixels SP are located in the display area DA on the substrate SUB. The sub-pixels SP may be arranged in a matrix shape along a first direction DR1, and along a second direction DR2 crossing the first direction DR1. However, embodiments are not limited thereto. For example, the sub-pixels SP may be arranged in a zigzag shape along the first direction DR1 and the second direction DR2. For example, the sub-pixels SP may be arranged in a PENTILE™ shape (PENTILE™ being a registered trademark of Samsung Display Co., Ltd., Republic of Korea). The first direction DR1 may be a row direction, and the second direction DR2 may be a column direction.

Two or more sub-pixels among the plurality of sub-pixels SP may configure one pixel PXL.

A component for controlling the sub-pixels SP may be located in the non-display area NDA on the substrate SUB. For example, lines connected to the sub-pixels SP, such as the first to m-th gate lines GL1 to GLm and the first to n-th data lines DL1 to DLn of FIG. 1, may be located in the non-display area NDA.

At least one of the gate driver 120, the data driver 130, the voltage generator 140, the controller 150, and the temperature sensor 160 of FIG. 1 may be integrated in the non-display area NDA of the display panel DP. In embodiments, the gate driver 120 of FIG. 1 may be mounted on the display panel DP and may be located in the non-display area NDA. In other embodiments, the gate driver 120 may be implemented as an integrated circuit separated from the display panel DP. In embodiments, the temperature sensor 160 may be located in the non-display area NDA to sense a temperature of the display panel DP.

The pads PD are located in the non-display area NDA on the substrate SUB. The pads PD may be electrically connected to the sub-pixels SP through lines. For example, the pads PD may be connected to the sub-pixels SP through the first to n-th data lines DL1 to DLn.

The pads PD may interface the display panel DP to other components of the display device 100 (refer to FIG. 1). In embodiments, voltages and signals suitable for an operation of components included in the display panel DP may be provided from the driver integrated circuit DIC of FIG. 1 through the pads PD. For example, the first to n-th data lines DL1 to DLn may be connected to the driver integrated circuit DIC through the pads PD. For example, the first and second power voltages VDD and VSS may be received from the driver integrated circuit DIC through the pads PD. For example, when the gate driver 120 is mounted on the display panel DP, the gate control signal GCS may be transmitted from the driver integrated circuit DIC to the gate driver 120 through the pads PD.

In embodiments, a circuit board may be electrically connected to the pads PD using a conductive adhesive member, such as an anisotropic conductive film. At this time, the circuit board may be a flexible circuit board (FPCB) or a flexible film having a flexible material. The driver integrated circuit DIC may be mounted on the circuit board to be electrically connected to the pads PD.

In embodiments, the display area DA may have various shapes. The display area DA may have a closed loop shape including straight and/or curved sides. For example, the display area DA may have shapes, such as a polygon, a circle, a semicircle, and an ellipse.

In embodiments, the display panel DP may have a flat display surface. In other embodiments, the display panel DP may have a display surface that is at least partially round. In embodiments, the display panel DP may be bendable, foldable, or rollable. In these cases, the display panel DP and/or the substrate SUB may include materials having a flexible property.

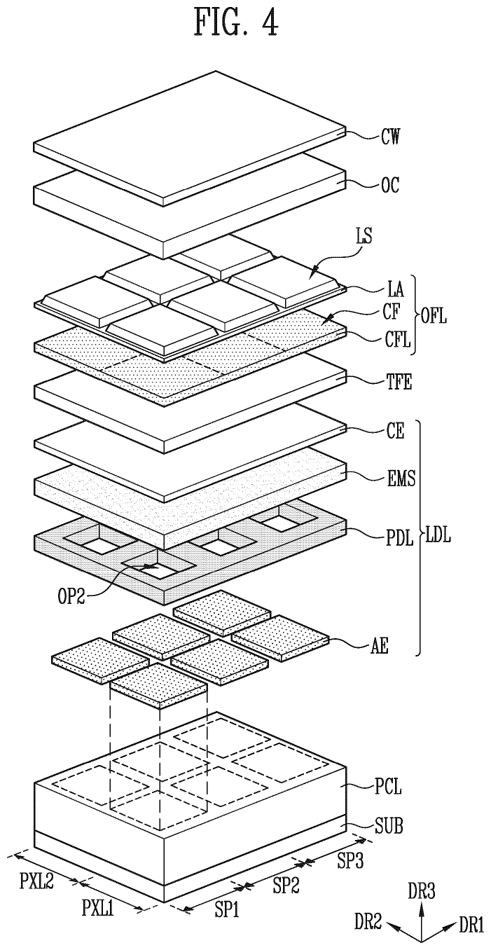

FIG. 4 is an exploded perspective view illustrating a portion of the display panel of FIG. 3. In FIG. 4, for clear and concise description, a portion of the display panel DP corresponding to two pixels PXL1 and PXL2 among the pixels PXL of FIG. 3 is schematically shown. A portion of the display panel DP corresponding to remaining pixels may be similarly configured.

Referring to FIGS. 3 and 4, each of the first and second pixels PXL1 and PXL2 may include first to third sub-pixels SP1, SP2, and SP3. However, embodiments are not limited thereto. For example, each of the first and second pixels PXL1 and PXL2 may include four sub-pixels or two sub-pixels.

In FIG. 4, the first to third sub-pixels SP1, SP2, and SP3 may have quadrangle shapes when viewed from a third direction DR3 crossing the first and second directions DR1 and DR2, and may have sizes equal to each other. However, embodiments are not limited thereto. The first to third sub-pixels SP1, SP2, and SP3 may be modified to have various shapes.

The display panel DP may include the substrate SUB, a pixel circuit layer PCL, a light-emitting element layer LDL, an encapsulation layer TFE, an optical functional layer OFL, an overcoat layer OC, and a cover window CW.

In embodiments, the substrate SUB may include a silicon wafer substrate formed using a semiconductor process. The substrate SUB may include a semiconductor material suitable for forming circuit elements. For example, the semiconductor material may include silicon, germanium, and/or silicon-germanium. The substrate SUB may be provided from a bulk wafer, an epitaxial layer, a silicon on insulator (SOI) layer, a semiconductor on insulator (SeOI) layer, or the like. In other embodiments, the substrate SUB may include a glass substrate. In still other embodiments, the substrate SUB may include a polyimide (PI) substrate.

The pixel circuit layer PCL is located on the substrate SUB. The substrate SUB and/or the pixel circuit layer PCL may include insulating layers and conductive patterns located between the insulating layers. The conductive patterns of the pixel circuit layer PCL may function as at least a portion of circuit elements, lines, and the like. The conductive patterns may include copper, but embodiments are not limited thereto.

The circuit elements may include the sub-pixel circuit SPC (refer to FIG. 2) for each of the first to third sub-pixels SP1, SP2, and SP3. The sub-pixel circuit SPC may include transistors and one or more capacitors. Each transistor may include a semiconductor portion including a source area, a drain area, and a channel area, and a gate electrode overlapping the semiconductor portion. In embodiments, when the substrate SUB is provided as a silicon substrate, the semiconductor portion may be included in the substrate SUB, and the gate electrode may be included in the pixel circuit layer PCL as a conductive pattern of the pixel circuit layer PCL. In embodiments, when the substrate SUB is provided as a glass substrate or a PI substrate, the semiconductor portion and the gate electrode may be included in the pixel circuit layer PCL. Each capacitor may include electrodes spaced apart from each other. For example, each capacitor may include electrodes spaced apart from each other on a plane defined by the first and second directions DR1 and DR2. For example, each capacitor may include electrodes spaced apart from each other in the third direction DR3 with an insulating layer interposed therebetween.

The lines of the pixel circuit layer PCL may include signal lines connected to each of the first to third sub-pixels SP1, SP2, and SP3, for example, a gate line, an emission control line, a data line, and the like. The lines may further include a line connected to the first power voltage node VDDN of FIG. 2. In addition, the lines may further include a line connected to the second power voltage node VSSN of FIG. 2.

The light-emitting element layer LDL may include the anode electrodes AE, a pixel-defining layer (e.g., a third insulating layer) PDL, a light-emitting structure EMS, and the cathode electrode CE.

The anode electrodes AE may be located on the pixel circuit layer PCL. The anode electrodes AE may contact the circuit elements of the pixel circuit layer PCL. The anode electrodes AE may include an opaque conductive material capable of reflecting light, but embodiments are not limited thereto.

The pixel-defining layer PDL is located on the anode electrodes AE. The pixel-defining layer PDL may include, or define, a second opening OP2 exposing a portion of each of the anode electrodes AE. The second opening(s) OP2 of the pixel-defining layer PDL may be understood as emission areas respectively corresponding to the first to third sub-pixels SP1, SP2, and SP3, respectively.

In embodiments, the pixel-defining layer PDL may include an inorganic material. In this case, the pixel-defining layer PDL may include a plurality of stacked inorganic layers. For example, the pixel-defining layer PDL may include silicon oxide SiOₓ and silicon nitride SiNₓ. In other embodiments, the pixel-defining layer PDL may include an organic material. However, a material of the pixel-defining layer PDL is not limited thereto.

The light-emitting structure EMS may be located on the anode electrodes AE exposed by the second opening OP2 of the pixel-defining layer PDL. The light-emitting structure EMS may include a light-emitting layer configured to generate light, an electron transport layer configured to transport an electron, a hole transport layer configured to transport a hole, and the like.

In embodiments, the light-emitting structure EMS may fill the second opening OP2 of the pixel-defining layer PDL, and may be entirely located on the pixel-defining layer PDL. In other words, the light-emitting structure EMS may extend across the first to third sub-pixels SP1, SP2, and SP3. In this case, at least a portion of layers in the light-emitting structure EMS may be disconnected or bent at boundaries between the first to third sub-pixels SP1, SP2, and SP3. However, embodiments are not limited thereto. For example, portions of the light-emitting structure EMS corresponding to the first to third sub-pixels SP1, SP2, and SP3 may be separated from each other, and each of the portions may be located in the second opening OP2 of the pixel-defining layer PDL.

The cathode electrode CE may be located on the light-emitting structure EMS. The cathode electrode CE may extend across the first to third sub-pixels SP1, SP2, and SP3. As described above, the cathode electrode CE may be provided as a common electrode for the first to third sub-pixels SP1, SP2, and SP3.

The cathode electrode CE may be a thin metal layer having a thickness sufficient to transmit light emitted from the light-emitting structure EMS. The cathode electrode CE may be formed of a metal material or a transparent conductive material to have a relatively thin thickness. In embodiments, the cathode electrode CE may include at least one of various transparent conductive materials including indium tin oxide, indium zinc oxide, indium tin zinc oxide, aluminum zinc oxide, gallium zinc oxide, zinc tin oxide, or gallium tin oxide. In other embodiments, the cathode electrode CE may include at least one of silver (Ag), magnesium (Mg), or a mixture thereof. However, a material of the cathode electrode CE is not limited thereto.

It may be understood that one of the anode electrodes AE, a portion of the light-emitting structure EMS overlapping it, and a portion of the cathode electrode CE overlapping it configure one light-emitting element LD (refer to FIG. 2). In other words, each of the light-emitting elements of the first to third sub-pixels SP1, SP2, and SP3 may correspond to one anode electrode, a portion of the light-emitting structure EMS overlapping it, and a portion of the cathode electrode CE overlapping it. In each of the first to third sub-pixels SP1, SP2, and SP3, holes injected from the anode electrode AE and electrons injected from the cathode electrode CE may be transported into the light-emitting layer of the light-emitting structure EMS to form excitons, and when the excitons transit from an excited state to a ground state, light may be generated. A luminance of light may be determined according to an amount of a current flowing through the light-emitting layer. According to a configuration of the light-emitting layer, a wavelength range of the generated light may be determined.

The encapsulation layer TFE is located on the cathode electrode CE. The encapsulation layer TFE may cover the light-emitting element layer LDL and/or the pixel circuit layer PCL. The encapsulation layer TFE may be configured to reduce or prevent permeation of oxygen, moisture, and/or the like to the light-emitting element layer LDL. In embodiments, the encapsulation layer TFE may include a structure in which one or more inorganic layers and one or more organic layers are alternately stacked. For example, the inorganic layer may include silicon nitride, silicon oxide, silicon oxynitride (SiOₓN_{y}), or the like. For example, the organic layer may include an organic insulating material, such as acrylic resin, epoxy resin, phenol resin, polyamide resin, polyimide resin, unsaturated polyesters resin, poly-phenylenether resin, polyphenylenesulfide resin, or benzocyclobutene (BCB) resin. However, materials of the organic layer and the inorganic layer of the encapsulation layer TFE are not limited thereto.

To improve an encapsulation efficiency of the encapsulation layer TFE, the encapsulation layer TFE may further include a thin film including aluminum oxide (AlOₓ). The thin film including the aluminum oxide may be positioned on an upper surface of the encapsulation layer TFE facing the optical functional layer OFL and/or a lower surface of the encapsulating layer TFE facing the light-emitting element layer LDL. For example, a thickness of the thin film including aluminum oxide may be about 300 Å to about 800 Å.

The thin film including the aluminum oxide may be formed through atomic layer deposition (ALD) method. However, embodiments are not limited thereto. The encapsulation layer TFE may further include a thin film formed of at least one of various materials suitable for improving the encapsulation efficiency.

The optical functional layer OFL is located on the encapsulation layer TFE. The optical functional layer OFL may include a color filter layer CFL and a lens array LA.

The color filter layer CFL is located between the encapsulation layer TFE and the lens array LA. The color filter layer CFL is configured to filter the light emitted from the light-emitting structure EMS, and to selectively output light of a wavelength range or a color corresponding to each sub-pixel. The color filter layer CFL may include color filters CF respectively corresponding to the first to third sub-pixels SP1, SP2, and SP3, and each of the color filters CF may pass light of a wavelength range corresponding to the corresponding sub-pixel. For example, the color filter corresponding to the first sub-pixel SP1 may pass red color light, the color filter corresponding to the second sub-pixel SP2 may pass green color light, and the color filter corresponding to the third sub-pixel SP3 may pass blue color light. According to the light emitted from the light-emitting structure EMS of each sub-pixel, at least a portion of the color filters CF may be omitted.

The lens array LA is located on the color filter layer CFL. The lens array LA may include lenses LS respectively corresponding to the first to third sub-pixels SP1, SP2, and SP3. Each of the lenses LS may improve light output efficiency by outputting the light emitted from the light-emitting structure EMS to an intended path. The lens array LA may have a relatively high refractive index. For example, the lens array LA may have a refractive index that is higher than that of the overcoat layer OC. In embodiments, the lenses LS may include an organic material. In embodiments, the lenses LS may include an acrylic material. However, a material of the lenses LS is not limited thereto.

In embodiments, compared to the second opening OP2 of the pixel-defining layer PDL, at least a portion of the color filters CF of the color filter layer CFL and at least a portion of the lenses LS of the lens array LA may be shifted in a direction parallel to the plane defined by the first and second directions DR1 and DR2. For example, in a central area of the display area DA, a center of a corresponding color filter and a center of a corresponding lens may be aligned with or overlap with a center of a corresponding second opening OP2 of the corresponding pixel-defining layer PDL when viewed in the third direction DR3. For example, in the central area of the display area DA, the second opening OP2 of the pixel-defining layer PDL may completely overlap the corresponding color filter of the color filter layer CFL and the corresponding lens of the lens array LA. In an area adjacent to the non-display area NDA in the display area DA, the center of the color filter and the center of the lens may be shifted in a plane direction from the center of the second opening OP2 of the corresponding pixel-defining layer PDL when viewed in the third direction DR3. For example, in the area adjacent to the non-display area NDA in the display area DA, the second opening OP2 of the pixel-defining layer PDL may partially overlap the corresponding color filter of the color filter layer CFL and the corresponding lens LS of the lens array LA. Accordingly, at a center of the display area DA, the light emitted from the light-emitting structure EMS may be efficiently output in a normal direction of a display surface. At an outskirt of the display area DA, the light emitted from the light-emitting structure EMS may be efficiently output in a direction inclined by an angle (e.g., predetermined angle) with respect to the normal direction of the display surface.

The overcoat layer OC may be located on the lens array LA. The overcoat layer OC may cover the optical functional layer OFL, the encapsulation layer TFE, the light-emitting structure EMS, and/or the pixel circuit layer PCL. The overcoat layer OC may include various materials suitable for protecting layers thereunder from a foreign substance, such as dust or moisture. For example, the overcoat layer OC may include at least one of an inorganic insulating layer or an organic insulating layer. For example, the overcoat layer OC may include epoxy, but embodiments are not limited thereto. The overcoat layer OC may have a refractive index that is lower than that of the lens array LA.

The cover window CW may be located on the overcoat layer OC. The cover window CW is configured to protect layers thereunder. The cover window CW may have a refractive index that is higher than that of the overcoat layer OC. The cover window CW may include glass, but embodiments are not limited thereto. For example, the cover window CW may be an encapsulation glass configured to protect components located thereunder. In other embodiments, the cover window CW may be omitted.

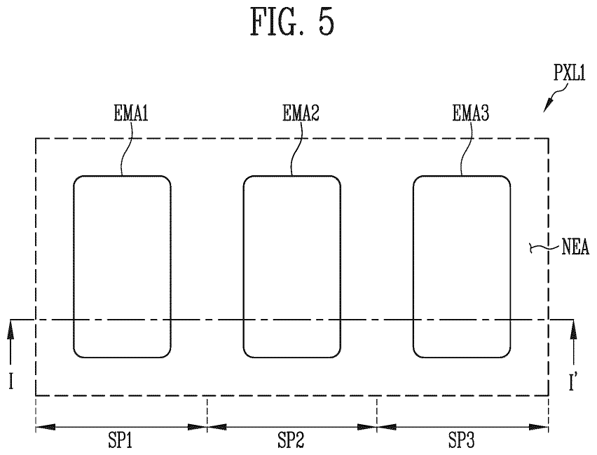

FIG. 5 is a plan view illustrating one or more embodiments of one of the pixels of FIG. 4. In FIG. 5, the first pixel PXL1 of the first and second pixels PXL1 and PXL2 of FIG. 4 is schematically shown for clear and concise description. The remaining pixels may be configured similarly to the first pixel PXL1.

Referring to FIGS. 4 and 5, the first pixel PXL1 may include the first to third sub-pixels SP1, SP2, and SP3 arranged in the first direction DR1.

The first sub-pixel SP1 may include a first emission area EMA1, and a non-emission area NEA around the first emission area EMA1. The second sub-pixel SP2 may include a second emission area EMA2, and a non-emission area NEA around the second emission area EMA2. The third sub-pixel SP3 may include a third emission area EMA3, and a non-emission area NEA around the third emission area EMA3.

The first emission area EMA1 may be an area where light is emitted from a portion of the light-emitting structure EMS (refer to FIG. 4) corresponding to the first sub-pixel SP1. The second emission area EMA2 may be an area where light is emitted from a portion of the light-emitting structure EMS corresponding to the second sub-pixel SP2. The third emission area EMA3 may be an area where light is emitted from a portion of the light-emitting structure EMS corresponding to the third sub-pixel SP3. As described with reference to FIG. 4, each emission area may be understood as the second opening OP2 of the pixel-defining layer PDL corresponding to each of the first to third sub-pixels SP1, SP2, and SP3.

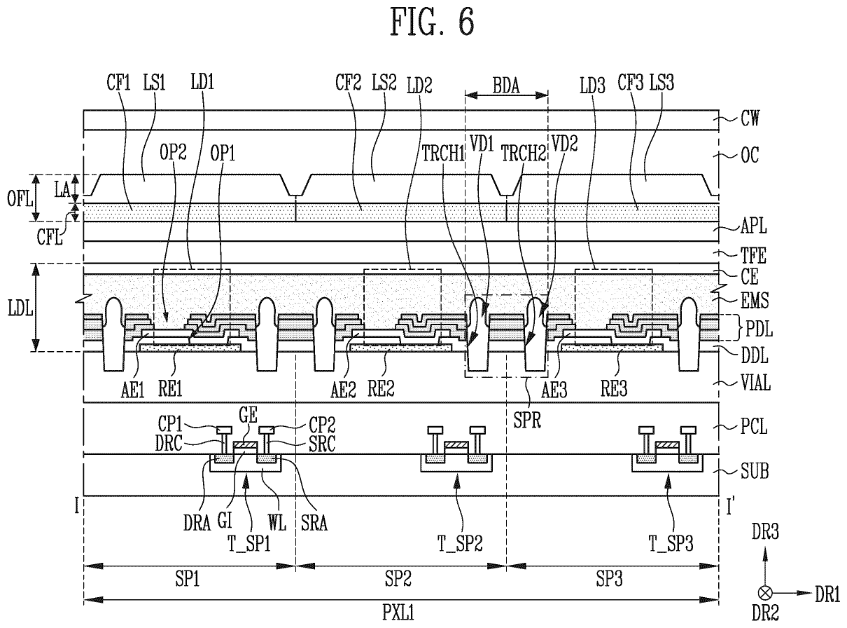

FIG. 6 is a cross-sectional view taken along the line I-I′ of FIG. 5.

Referring to FIG. 6, the substrate SUB and the pixel circuit layer PCL located on the substrate SUB are provided.

The substrate SUB may include a silicon wafer substrate formed using a semiconductor process. For example, the substrate SUB may include silicon, germanium, and/or silicon-germanium.

The pixel circuit layer PCL is located on the substrate SUB. The substrate SUB and the pixel circuit layer PCL may include circuit elements of each of the first to third sub-pixels SP1, SP2, and SP3. For example, the substrate SUB and the pixel circuit layer PCL may include a transistor T_SP1 of the first sub-pixel SP1, a transistor T_SP2 of the second sub-pixel SP2, and a transistor T_SP3 of the third sub-pixel SP3. The transistor T_SP1 of the first sub-pixel SP1 may be one of the transistors included in the sub-pixel circuit SPC (refer to FIG. 2) of the first sub-pixel SP1, the transistor T_SP2 of the second sub-pixel SP2 may be one of the transistors included in the sub-pixel circuit SPC of the second sub-pixel SP2, and the transistor T_SP3 of the third sub-pixel SP3 may be one of the transistors included in the sub-pixel circuit SPC of the third sub-pixel SP3. In FIG. 6, for clear and concise description, one of the transistors of each sub-pixel is shown, and the remaining circuit elements are omitted.

The transistor T_SP1 of the first sub-pixel SP1 may include a source area SRA, a drain area DRA, and a gate electrode GE.

The source area SRA and drain area DRA may be located in the substrate SUB. A well WL formed through an ion injection process may be located in, or defined by, the substrate SUB, and the source area SRA and the drain area DRA may be located to be spaced apart from each other in the well WL. An area between the source area SRA and the drain area DRA in the well WL may be defined as a channel area.

The gate electrode GE may overlap the channel area between the source area SRA and the drain area DRA, and may be located in the pixel circuit layer PCL. The gate electrode GE may be spaced apart from the well WL or the channel area by an insulating material, such as a gate insulating layer GI. The gate electrode GE may include a conductive material.

A plurality of layers included in the pixel circuit layer PCL may include insulating layers and conductive patterns located between the insulating layers, and such conductive patterns may include first and second conductive patterns CP1 and CP2. The first conductive pattern CP1 may be electrically connected to the drain area DRA through a drain connection portion DRC passing through one or more insulating layers. The second conductive pattern CP2 may be electrically connected to the source area SRA through a source connection portion SRC passing through one or more insulating layers.

As the gate electrode GE and the first and second conductive patterns CP1 and CP2 are connected to different circuit elements and/or lines, the transistor T_SP1 of the first sub-pixel SP1 may be provided as one of the transistors of the first sub-pixel SP1.

Each of the transistor T_SP2 of the second sub-pixel SP2 and the transistor T_SP3 of the third sub-pixel SP3 may be configured similarly to the transistor T_SP1 of the first sub-pixel SP1.

As described above, the substrate SUB and the pixel circuit layer PCL may include the circuit elements of each of the first to third sub-pixels SP1, SP2, and SP3.

A via layer (e.g., a first insulating layer) VIAL is located on the pixel circuit layer PCL. The via layer VIAL may cover the pixel circuit layer PCL, and may have an overall flat surface. The via layer VIAL is configured to planarize steps on the pixel circuit layer PCL. The via layer VIAL may include at least one of silicon oxide (SiOₓ), silicon nitride (SiNₓ), or silicon carbon nitride (SiCN), but embodiments are not limited thereto.

The light-emitting element layer LDL is located on the via layer VIAL. The light-emitting element layer LDL may include first to third reflective electrodes (e.g., a first electrodes) RE1, RE2, and RE3, a differential layer (e.g., a second insulating layer) DDL, first to third anode electrodes AE1, AE2, and AE3, the pixel-defining layer PDL, the light-emitting structure EMS, and the cathode electrode CE.

On the via layer VIAL, the first to third reflective electrodes RE1, RE2, and RE3 are located in the first to third sub-pixels SP1, SP2, and SP3, respectively. Each of the first to third reflective electrodes RE1, RE2, and RE3 may contact the circuit element located in the pixel circuit layer PCL through a via passing through the via layer VIAL.

The first to third reflective electrodes RE1, RE2, and RE3 may function as a full mirror reflecting the light emitted from the light-emitting structure EMS toward the display surface (or the cover window CW). The first to third reflective electrodes RE1, RE2, and RE3 may include metal materials suitable for reflecting light. The first to third reflective electrodes RE1, RE2, and RE3 may include at least one of aluminum (AI), silver (Ag), magnesium (Mg), platinum (Pt), palladium (Pd), gold (Au), nickel (Ni), neodymium (Nd), iridium (Ir), chromium (Cr), titanium (Ti), or an alloy of two or more materials selected from them. In one or more embodiments, the first to third reflective electrodes RE1, RE2, and RE3 may be formed in a multilayer structure of titanium nitride (TiN)/aluminum (AI)/titanium (Ti). In this case, a thickness of titanium nitride (TiN) may be about 35 Å to about 150 Å, a thickness of aluminum (AI) may be about 250 Å to about 1350 Å, and a thickness of titanium (Ti) may be about 50 Å to about 150 Å. A material of the first to third reflective electrodes RE1, RE2, and RE3 is not limited thereto.

In embodiments, a connection electrode may be located under each of the first to third reflective electrodes RE1, RE2, and RE3. The connection electrode may improve an electrical connection characteristic between a corresponding reflective electrode and the circuit element of the pixel circuit layer PCL. The connection electrode may have a multilayer structure. The multilayer structure may include titanium (Ti), titanium nitride (TiN), tantalum nitride (TaN), or the like, but embodiments are not limited thereto. In embodiments, a corresponding reflective electrode may be positioned between multiple layers of the connection electrode.

The differential layer DDL is located on the first to third reflective electrodes RE1, RE2, and RE3 and the via layer VIAL. The differential layer DDL may be formed on the via layer VIAL and the first to third reflective electrodes RE1, RE2, and RE3 along a curve of the via layer VIAL and the first to third reflective electrodes RE1, RE2, and RE3. That is, the differential layer DDL may be formed along the curve without a planarization process. Accordingly, the planarization process of the differential layer DDL may be omitted in a manufacturing process of the display device, and a manufacturing process of the display device may be simplified. The differential layer DDL may include at least one of silicon oxide (SiOₓ), silicon nitride (SiNₓ), or silicon carbon nitride (SiCN). For example, a thickness of the differential layer DDL may be about 150 Å to about 3000 Å. However, a material of the differential layer DDL is not limited thereto.

The first to third reflective electrodes RE1, RE2, and RE3 may function as full mirrors, and the cathode electrode CE may function as a half mirror. The light emitted from the light-emitting layer of the light-emitting structure EMS may be amplified by at least partially reciprocating between a corresponding reflective electrode and the cathode electrode CE, and the amplified light may be output through the cathode electrode CE. As described above, a distance between each reflective electrode and the cathode electrode CE may be understood as a resonance distance for the light emitted from the light-emitting layer of the corresponding light-emitting structure EMS.

For light reflected from the first to third reflective electrodes RE1, RE2, and RE3 to resonate, a distance (e.g., a resonance distance) between the first to third reflective electrodes RE1, RE2, and RE3 and the cathode electrode CE is suitably adjusted. The resonance distance may be adjusted by the differential layer DDL. For example, as the differential layer DDL is located between the first reflective electrode RE1 and the cathode electrode CE, the distance between the first reflective electrode RE1 and the cathode electrode CE may be adjusted.

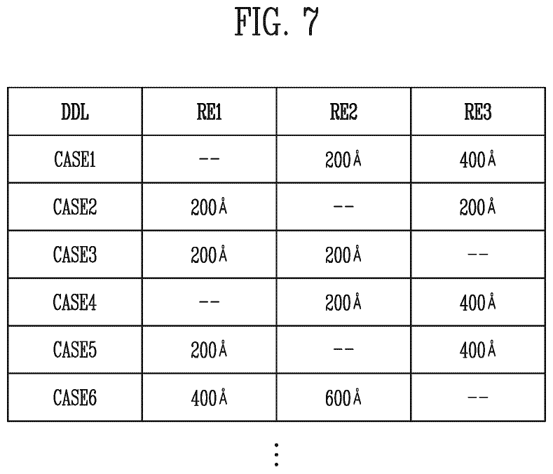

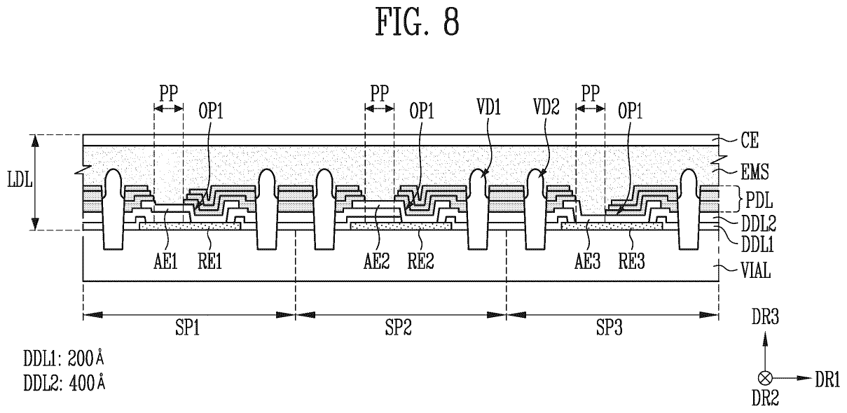

In one or more embodiments, at least two of the first to third sub-pixels SP1, SP2, and SP3 may have different resonance distances. A detailed description of this is provided later with reference to FIGS. 7 and 8. The resonance distance adjusted as described above may allow light to be effectively and efficiently amplified.

The differential layer DDL may include, or define, a first opening OP1 exposing at least a portion of each of the first to third reflective electrodes RE1, RE2, and RE3. The first to third anode electrodes AE1, AE2, and AE3 may be located on the first opening OP1 and the differential layer DDL. The first to third anode electrodes AE1, AE2, and AE3 may have shapes similar to the first to third emission areas EMA1, EMA2, and EMA3 of FIG. 5 when viewed in the third direction DR3. The first to third anode electrodes AE1, AE2, and AE3 may directly contact (e.g., may be connected to) the first to third reflective electrodes RE1, RE2, and RE3 through the first opening OP1. Accordingly, a process of forming a via for connecting the first to third anode electrodes AE1, AE2, and AE3 to the first to third reflective electrodes RE1, RE2, and RE3 may be omitted, and a manufacturing process of the display device may be simplified.

In embodiments, the first to third anode electrodes AE1, AE2, and AE3 may include at least one of transparent conductive materials, such as indium tin oxide (ITO), indium zinc oxide (IZO), zinc oxide (ZnOₓ), indium gallium zinc oxide (IGZO), or indium tin zinc oxide (ITZO). For example, a thickness of the first to third anode electrodes AE1, AE2, and AE3 may be about 50 Å to about 450 Å. However, a material of the first to third anode electrodes AE1, AE2, and AE3 is not limited thereto. For example, the first to third anode electrodes AE1, AE2, and AE3 may include titanium nitride.

The pixel-defining layer PDL is located on portions of the first to third anode electrodes AE1, AE2, and AE3 and the differential layer DDL. The pixel-defining layer PDL may include/define the second opening OP2 exposing a portion of each of the first to third anode electrodes AE1, AE2, and AE3. The second opening OP2 of the pixel-defining layer PDL may define the emission area of each of the first to third sub-pixels SP1, SP2, and SP3. As described above, the pixel-defining layer PDL may be located in the non-emission area NEA of FIG. 5, and may define the first to third emission areas EMA1, EMA2, and EMA3 of FIG. 5.

In one or more embodiments, the pixel-defining layer PDL may be located on an area where the respective first to third anode electrodes AE1, AE2, and AE3 directly contact the corresponding first to third reflective electrodes RE1, RE2, and RE3. That is, the pixel-defining layer PDL may be located on the first opening OP1.

In embodiments, the pixel-defining layer PDL may include a plurality of inorganic insulating layers. Each of the plurality of inorganic insulating layers may include at least one of silicon oxide (SiOₓ) or silicon nitride (SiNₓ). For example, the pixel-defining layer PDL may include sequentially stacked first to third inorganic insulating layers, and each of the first to third inorganic insulating layers may include silicon nitride, silicon oxide, and silicon oxynitride. For example, a thickness of the pixel-defining layer PDL may be less than about 450 Å. However, a material of the pixel-defining layer PDL is not limited thereto. The first to third inorganic insulating layers may have a step shape of cross-section in an area adjacent to the second opening OP2.

It is illustrated that the pixel-defining layer PDL is configured of a plurality of layers, but the disclosure is not limited thereto. For example, the pixel-defining layer PDL may be configured of a single layer.

A separator SPR may be provided in a boundary area BDA between sub-pixels neighboring each other. In other words, the separator SPR may be provided in each of the boundary areas between the sub-pixels SP of FIG. 3.

The separator SPR may cause formation of a discontinuity in the light-emitting structure EMS in the boundary area BDA. For example, the light-emitting structure EMS may be disconnected or bent in the boundary area BDA due to the separator SPR.

The separator SPR may be provided in or on the pixel-defining layer PDL. The pixel-defining layer PDL may include one or more trenches TRCH1 and TRCH2 as the separator SPR in the boundary area BDA. In embodiments, as shown in FIG. 6, one or more trenches TRCH1 and TRCH2 may pass through the differential layer DDL, and may partially pass through the via layer VIAL. In other embodiments, one or more trenches TRCH1 and TRCH2 may pass through the pixel-defining layer PDL, and may partially pass through the differential layer DDL. In other embodiments, one or more trenches TRCH1 and TRCH2 may at least partially pass through the differential layer DDL and/or the via layer VIAL, and a portion of the pixel-defining layer PDL may be located in one or more trenches TRCH1 and TRCH2.

In FIG. 6, the two trenches TRCH1 and TRCH2 are provided in the boundary area BDA. However, embodiments are not limited thereto. For example, the pixel-defining layer PDL may include one trench in the boundary area BDA. Alternatively, the pixel-defining layer PDL may include three or more trenches in the boundary area BDA.

Due to the first and second trenches TRCH1 and TRCH2, in the boundary area BDA, discontinuous portions, such as a first void VD1 and a second void VD2 may be formed in the light-emitting structure EMS. A portion of a plurality of layers stacked in the light-emitting structure EMS may be disconnected or bent by the first and second voids VD1 and VD2. For example, at least one charge generation layer included in the light-emitting structure EMS may be disconnected in the first and second voids VD1 and VD2. As described above, portions of the light-emitting structure EMS included in the first to third sub-pixels SP1, SP2, and SP3 may be at least partially separated due to the first and second trenches TRCH1 and TRCH2. A width of the first direction DR1 of the first and second trenches TRCH1 and TRCH2 may be about 300 Å to about 1500 Å, and a height of the third direction DR3 of the first and second trenches TRCH1 and TRCH2 may be about 1000 Å to about 8000 Å.

In FIG. 6, in the boundary area BDA, the first and second voids VD1 and VD2 are formed in the light-emitting structure EMS, but this is only an example, and embodiments are not limited thereto. For example, in the boundary area BDA, a valley of a concave shape may be formed in the light-emitting structure EMS. According to shapes of the first and second trenches TRCH1 and TRCH2, discontinuous portions formed in the light-emitting structure EMS may be variously changed.

In embodiments, the light-emitting structure EMS may be formed through a process of vacuum deposition, inkjet printing, and the like. In this case, the same materials as the light-emitting structure EMS may be positioned on bottom surfaces of the first and second trenches TRCH1 and TRCH2 adjacent to the via layer VIAL.

The separator SPR may be variously modified and provided so that the light-emitting structure EMS may have a discontinuous portion in the boundary area BDA. In embodiments, inorganic insulating patterns additionally stacked on the pixel-defining layer PDL may be provided in the boundary area BDA without the first and second trenches TRCH1 and TRCH2. Among the additionally stacked inorganic insulating patterns, a width of the uppermost inorganic insulating pattern may be greater than a width of an inorganic insulating pattern located immediately thereunder. For example, in the boundary area BDA, first to third inorganic insulating patterns may be sequentially stacked from the pixel-defining layer PDL, and the uppermost third inorganic insulating pattern may have a width that is greater than that of the second inorganic insulating pattern. For example, the pixel-defining layer PDL may have a “T” shape or an “I” shape of cross-section in the boundary area BDA. According to a shape of the pixel-defining layer PDL, a plurality of layers included in the light-emitting structure EMS may be at least partially disconnected or bent in the boundary area BDA.

The light-emitting structure EMS may be located on the first to third anode electrodes AE1, AE2, and AE3 exposed by the second opening OP2 of the pixel-defining layer PDL. The light-emitting structure EMS may fill the second opening OP2 of the pixel-defining layer PDL, and may be located entirely across the first to third sub-pixels SP1, SP2, and SP3. As described above, the light-emitting structure EMS may be at least partially disconnected or bent in the boundary area BDA by the separator SPR. Accordingly, when the display panel DP is operated, there may be a decrease in a current flowing out from each of the first to third sub-pixels SP1, SP2, and SP3 to a sub-pixel adjacent thereto through layers included in the light-emitting structure EMS. Therefore, the first to third light-emitting elements LD1, LD2, and LD3 may operate with relatively high reliability. For example, a thickness of the light-emitting structure EMS may be about 2000 Å to about 9000 Å.

The cathode electrode CE may be located on the light-emitting structure EMS. The cathode electrode CE may be commonly provided to the first to third sub-pixels SP1, SP2, and SP3. The cathode electrode CE may function as a half mirror that partially transmits and partially reflects the light emitted from the light-emitting structure EMS.

The first anode electrode AE1, a portion of the light-emitting structure EMS overlapping the first anode electrode AE1, and a portion of the cathode electrode CE overlapping the first anode electrode AE1 may configure the first light-emitting element LD1. The second anode electrode AE2, a portion of the light-emitting structure EMS overlapping the second anode electrode AE2, and a portion of the cathode electrode CE overlapping the second anode electrode AE2 may configure the second light-emitting element LD2. The third anode electrode AE3, a portion of the light-emitting structure EMS overlapping the third anode electrode AE3, and a portion of the cathode electrode CE overlapping the third anode electrode AE3 may configure the third light-emitting element LD3.

The encapsulation layer TFE is located on the cathode electrode CE. The encapsulation layer TFE may reduce or prevent permeation of oxygen, moisture, and/or the like to the light-emitting element layer LDL. In one or more embodiments, the encapsulation layer TFE may include at least one of silicon nitride (SiNₓ) or a monomer-based material. In one or more embodiments, the encapsulation layer TFE may be formed of multiple layers of silicon nitride (SiNₓ)/monomer-based material/silicon nitride (SiNₓ). In this case, a thickness of silicon nitride (SiNₓ) may be about 4000 Å to about 10000 Å, and a thickness of the monomer-based material may be about 0.5 μm to about 4.5 μm. However, a material of the encapsulation layer TFE is not limited thereto, and the encapsulation layer TFE does not necessarily have to be formed of multiple layers.

The optical functional layer OFL is located on the encapsulation layer TFE. In embodiments, the optical functional layer OFL may be attached to the encapsulation layer TFE through an adhesive layer APL. For example, the optical functional layer OFL may be separately manufactured and attached to the encapsulation layer TFE through the adhesive layer APL. The adhesive layer APL may further perform a function of protecting lower layers including the encapsulation layer TFE.

The optical functional layer OFL may include the color filter layer CFL and the lens array LA. The color filter layer CFL may include first to third color filters CF1, CF2, and CF3 respectively corresponding to the first to third sub-pixels SP1, SP2, and SP3. The first to third color filters CF1, CF2, and CF3 may pass light of different wavelength ranges. For example, the first to third color filters CF1, CF2, and CF3 may pass light of red, green, and blue colors, respectively. For example, a thickness of the first to third color filters CF1, CF2, and CF3 may be about 6000 Å to about 22000 Å.

In embodiments, the first to third color filters CF1, CF2, and CF3 may partially overlap in the boundary area BDA. In other embodiments, the first to third color filters CF1, CF2, and CF3 may be spaced apart from each other, and a black matrix may be provided between the first to third color filters CF1, CF2, and CF3.

The lens array LA is located on the color filter layer CFL. The lens array LA may include first to third lenses LS1, LS2, and LS3 respectively corresponding to the first to third sub-pixels SP1, SP2, and SP3. For example, a thickness of the first to third lenses LS1, LS2, and LS3 may be about 10,000 Å to about 30,000 Å. Each of the first to third lenses LS1, LS2, and LS3 may improve light output efficiency by outputting light emitted from the first to third light-emitting elements LD1, LD2, and LD3 to an intended path.

FIG. 7 is a table illustrating examples of a thickness of the differential layer of FIG. 6, and FIG. 8 is a cross-sectional view illustrating CASE6 of FIG. 7.

For convenience of description, in FIG. 8, some configurations, not including the via layer VIAL, the first to third reflective electrodes RE1, RE2, and RE3, first and second differential layers (e.g., a (2-1)-th insulating layer and a (2-2)-th insulating layer) DDL1 and DDL2, the pixel-defining layer PDL, the first to third anode electrodes AE1, AE2, and AE3, the light-emitting structure EMS, and the cathode electrode CE, may be omitted.

Referring to FIGS. 7 and 8, the thickness of the differential layer DDL formed on a portion PP of each of the first to third reflective electrodes RE1, RE2, and RE3 may be different in at least two of the first to third sub-pixels SP1, SP2, and SP3. The resonance distance may be different for each of the sub-pixels SP1, SP2, and SP3. Therefore, the resonance distance for each of the sub-pixels SP1, SP2, and SP3 may be suitably adjusted by varying the thickness of the differential layer DDL for each of the sub-pixels SP1, SP2, and SP3. The thickness of the differential layer DDL formed on the portion PP of each of the first to third reflective electrodes RE1, RE2, and RE3 may be experimentally determined.

For example, in a case of CASE1, the thickness of the differential layer DDL formed on the portion PP of the first reflective electrode RE1 may be about 0 Å, the thickness of the differential layer DDL formed on the portion PP of the second reflective electrode RE2 may be about 200 Å, and the thickness of the differential layer DDL formed on the portion PP of the third reflective electrode RE3 may be about 400 Å.

For example, in a case of CASE2, the thickness of the differential layer DDL formed on the portion PP of the first reflective electrode RE1 may be about 200 Å, the thickness of the differential layer DDL formed on the portion PP of the second reflective electrode RE2 may be about 0 Å, and the thickness of the differential layer DDL formed on the portion PP of the third reflective electrode RE3 may be about 200 Å.

For example, in a case of CASE3, the thickness of the differential layer DDL formed on the portion PP of the first reflective electrode RE1 may be about 200 Å, the thickness of the differential layer DDL formed on the portion PP of the second reflective electrode RE2 may be about 200 Å, and the thickness of the differential layer DDL formed on the portion PP of the third reflective electrode RE3 may be about 0 Å.

For example, in a case of CASE4, the thickness of the differential layer DDL formed on the portion PP of the first reflective electrode RE1 may be about 0 Å, the thickness of the differential layer DDL formed on the portion PP of the second reflective electrode RE2 may be about 200 Å, and the thickness of the differential layer DDL formed on the portion PP of the third reflective electrode RE3 may be about 400 Å.

For example, in a case of CASE5, the thickness of the differential layer DDL formed on the portion PP of the first reflective electrode RE1 may be about 200 Å, the thickness of the differential layer DDL formed on the portion PP of the second reflective electrode RE2 may be about 0 Å, and the thickness of the differential layer DDL formed on the portion PP of the third reflective electrode RE3 may be about 400 Å.

For example, in a case of CASE6, the thickness of the differential layer DDL formed on the portion PP of the first reflective electrode RE1 may be about 400 Å, the thickness of the differential layer DDL formed on the portion PP of the second reflective electrode RE2 may be about 600 Å, and the thickness of the differential layer DDL formed on the part PP of the third reflective electrode RE3 may be about 0 Å.

Here, when the differential layer DDL is omitted, the thickness of the differential layer DDL is set to about 0 Å.

Six cases are illustrated, but the disclosure is not limited to these six cases.

In one or more embodiments, the differential layer DDL may include the first differential layer DDL1 and the second differential layer DDL2. Each of the first differential layer DDL1 and the second differential layer DDL2 may be selectively located on the portion PP of each of the first to third reflective electrodes RE1, RE2, and RE3. For example, on the portion PP of the first to third reflective electrodes RE1, RE2, and RE3, both of the first differential layer DDL1 and the second differential layer DDL2 may be omitted, only one of the first differential layer DDL1 or the second differential layer DDL2 may be present, or both of the first differential layer DDL1 and the second differential layer DDL2 may be present, according to the resonance distance.

For example, as shown in FIG. 8 (e.g., CASE6), it is assumed that a thickness of the first differential layer DDL1 is about 200 Å and a thickness of the second differential layer DDL2 is about 400 Å. In this case, the second differential layer DDL2 may be located on the portion PP of the first reflective electrode RE1, the first differential layer DDL1 and the second differential layer DDL2 may be located on the portion PP of the second reflective electrode RE2, and both of the first differential layer DDL1 and the second differential layer DDL2 may be omitted from the portion PP of the third reflective electrode RE3.

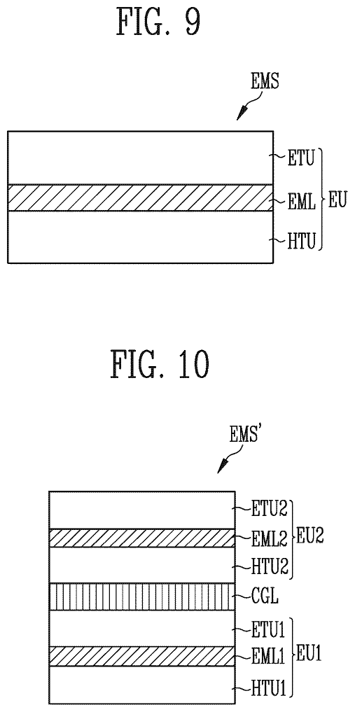

FIG. 9 is a cross-sectional view illustrating one or more embodiments of a light-emitting structure included in one of the first to third light-emitting elements of FIG. 6.

Referring to FIG. 9, the light-emitting structure EMS may have a light-emitting unit EU. The light-emitting structure EMS may be configured substantially equally in each of the first to third light-emitting elements LD1, LD2, and LD3 of FIG. 6.

The light-emitting unit EU may include at least one light-emitting unit EU that generates light according to an applied current. The light-emitting unit EU may include a light-emitting layer EML, an electron transport unit ETU, and a hole transport unit HTU. The light-emitting layer EML may be located between the electron transport unit ETU and the hole transport unit HTU.

Each hole transport unit HTU may include at least one of a hole injection layer or a hole transport layer, and may further include a hole buffer layer, an electron-blocking layer, and the like if suitable.

Each electron transport unit ETU may include at least one of an electron injection layer or an electron transport layer, and may further include an electron buffer layer, a hole-blocking layer, and the like if suitable.

The light-emitting layer EML may generate white light. For example, the light-emitting layer EML may include a structure in which a first sub light-emitting layer configured to generate light of a first color, and a second sub light-emitting layer configured to generate light of a second color, are stacked. The light of the first color and the light of the second color may be mixed to generate white light or light of a color close to white light. In this case, an intermediate layer, which is configured to perform a function of transporting holes and/or reducing or preventing transport of electrons, may be further located between the first and second sub light-emitting layers. However, the disclosure is not limited to a method by which the light-emitting layer EML generates white light, and is not limited to white light.

The light-emitting structure EMS may be formed through methods, such as vacuum deposition and inkjet printing, but embodiments are not limited thereto.

FIG. 10 is a cross-sectional view illustrating one or more other embodiments of a light-emitting structure included in one of the first to third light-emitting elements of FIG. 6.

Referring to FIG. 10, the light-emitting structure EMS' may have a tandem structure in which first and second light-emitting units EU1 and EU2 are stacked. The light-emitting structure EMS' may be configured substantially equally in each of the first to third light-emitting elements LD1, LD2, and LD3 of FIG. 6.

Each of the first and second light-emitting units EU1 and EU2 may include at least one light-emitting layer that generates light according to an applied current. The first light-emitting unit EU1 may include a first light-emitting layer EML1, a first electron transport unit ETU1, and a first hole transport unit HTU1. The first light-emitting layer EML1 may be located between the first electron transport unit ETU1 and the first hole transport unit HTU1. The second light-emitting unit EU2 may include a second light-emitting layer EML2, a second electron transport unit ETU2, and a second hole transport unit HTU2. The second light-emitting layer EML2 may be located between the second electron transport unit ETU2 and the second hole transport unit HTU2.

Each of the first and second hole transport units HTU1 and HTU2 may include at least one of a hole injection layer or a hole transport layer, and may further include a hole buffer layer, an electron-blocking layer, and the like if suitable. The first and second hole transport units HTU1 and HTU2 may have configurations equal to each other or different from each other.

Each of the first and second electron transport units ETU1 and ETU2 may include at least one of an electron injection layer or an electron transport layer, and may further include an electron buffer layer, a hole-blocking layer, and the like if suitable. The first and second electron transport units ETU1 and ETU2 may have configurations equal to each other or different from each other.

A connection layer, which may be provided in a form of a charge generation layer CGL, may be located between the first light-emitting unit EU1 and the second light-emitting unit EU2 to connect the first light-emitting unit EU1 and the second light-emitting unit EU2 to each other. In embodiments, the charge generation layer CGL may have a stack structure of a p dopant layer and an n dopant layer. For example, the p dopant layer may include a p-type dopant, such as HAT-CN, TCNQ, and NDP-9, and the n dopant layer may include an alkali metal, an alkaline earth metal, a lanthanide metal, or a combination thereof. However, embodiments are not limited thereto.

In embodiments, the first light-emitting layer EML1 and the second light-emitting layer EML2 may generate light of different respective colors. Light emitted from each of the first light-emitting layer EML1 and the second light-emitting layer EML2 may be mixed and viewed as white light. For example, the first light-emitting layer EML1 may generate blue light, and the second light-emitting layer EML2 may generate yellow light. In embodiments, the second light-emitting layer EML2 may include a structure in which a first sub light-emitting layer configured to generate red light and a second sub light-emitting layer configured to generate green light are stacked. The red light and the green light may be mixed, and thus the yellow light may be provided. In this case, an intermediate layer configured to perform a function of transporting holes and/or blocking transport of electrons may be further located between the first and second sub light-emitting layers.

In other embodiments, the first light-emitting layer EML1 and the second light-emitting layer EML2 may generate light of the same color.

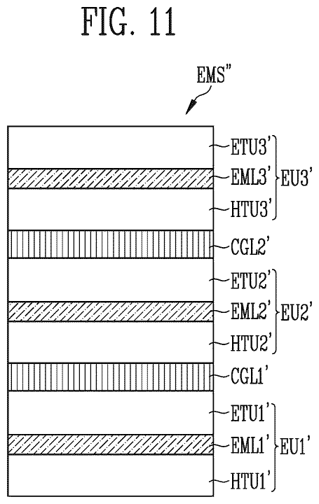

FIG. 11 is a cross-sectional view illustrating still one or more other embodiments of a light-emitting structure included in one of the first to third light-emitting elements of FIG. 6.

Referring to FIG. 11, the light-emitting structure EMS″ may have a tandem structure in which first to third light-emitting units EU1′, EU2′, and EU3′ are stacked. The light-emitting structure EMS″ may be configured substantially equally in each of the first to third light-emitting elements LD1, LD2, and LD3 of FIG. 6.

Each of the first to third light-emitting units EU1′, EU2′, and EU3′ may include a light-emitting layer that generates light according to an applied current. The first light-emitting unit EU1′ may include a first light-emitting layer EML1′, a first electron transport unit ETU1′, and a first hole transport unit HTU1′. The first light-emitting layer EML1′ may be located between the first electron transport unit ETU1′ and the first hole transport unit HTU1′. The second light-emitting unit EU2′ may include a second light-emitting layer EML2′, a second electron transport unit ETU2′, and a second hole transport unit HTU2′. The second light-emitting layer EML2′ may be located between the second electron transport unit ETU2′ and the second hole transport unit HTU2′.

The third light-emitting unit EU3′ may include a third light-emitting layer EML3′, a third electron transport unit ETU3′, and a third hole transport unit HTU3′. The third light-emitting layer EML3′ may be located between the third electron transport unit ETU3′ and the third hole transport unit HTU3′.

Each of the first to third hole transport units HTU1′, HTU2′, and HTU3′ may include at least one of a hole injection layer or a hole transport layer, and may further include a hole buffer layer, an electron-blocking layer, and the like if suitable. The first to third hole transport units HTU1′, HTU2′, and HTU3′ may have configurations equal to each other or different from each other.

Each of the first to third electron transport units ETU1′, ETU2′, and ETU3′ may include at least one of an electron injection layer or an electron transport layer, and may further include an electron buffer layer, a hole-blocking layer, and the like, if suitable. The first to third electron transport units ETU1′, ETU2′, and ETU3′ may have configurations equal to each other or different from each other.

A first charge generation layer CGL1′ is located between the first light-emitting unit EU1′ and the second light-emitting unit EU2′. A second charge generation layer CGL2′ is located between the second light-emitting unit EU2′ and the third light-emitting unit EU3′.

In embodiments, the first to third light-emitting layers EML1′, EML2′, and EML3′ may generate light of different colors. Light emitted from each of the first to third light-emitting layers EML1′, EML2′, and EML3′ may be mixed and may be viewed as white light. For example, the first light-emitting layer EML1′ may generate light of a blue color, the second light-emitting layer EML2′ may generate light of a green color, and the third light-emitting layer EML3′ may generate light of a red color.

In other embodiments, two or more of the first to third light-emitting layers EML1′, EML2′, or EML3′ may generate light of the same color.

In one or more embodiments, differently from that shown in FIGS. 9 to 11, the light-emitting structure EMS of FIG. 6 may include one light-emitting unit in each of the first to third light-emitting elements LD1, LD2, and LD3, and the light-emitting unit included in each of the first to third light-emitting elements LD1, LD2, and LD3 may be configured to emit light of different colors. For example, the light-emitting unit of the first light-emitting element LD1 may emit the light of the red color, the light-emitting unit of the second light-emitting element LD2 may emit the light of the green color, and the light-emitting unit of the third light-emitting element LD3 may emit the light of the blue color. In this case, differently from that shown in FIG. 6, the light-emitting units of the first to third sub-pixels SP1, SP2, and SP3 may be separated from each other, and each of them may be located in the second opening OP2 of the pixel-defining layer PDL. In this case, at least a portion of the color filters CF1, CF2, and CF3 may be omitted.

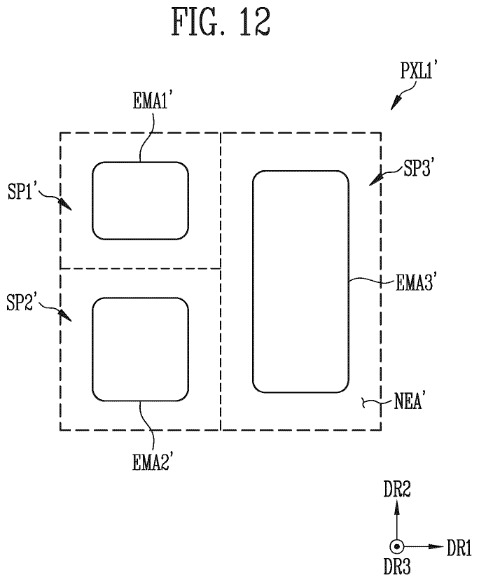

FIG. 12 is a plan view illustrating one or more other embodiments of one of the pixels of FIG. 4.

Referring to FIG. 12, a first pixel PXL1′ may include first to third sub-pixels SP1′, SP2′, and SP3′.

The first sub-pixel SP1′ may include a first emission area EMA1′, and a non-emission area NEA′ around the first emission area EMA1′. The second sub-pixel SP2′ may include a second emission area EMA2′, and a non-emission area NEA′ around the second emission area EMA2′. The third sub-pixel SP3′ may include a third emission area EMA3′, and a non-emission area NEA′ around the third emission area EMA3′.

The first sub-pixel SP1′ and the second sub-pixel SP2′ may be arranged in the second direction DR2. The third sub-pixel SP3′ may be arranged in the first direction DR1 with respect to each of the first and second sub-pixels SP1′ and SP2′.

The second sub-pixel SP2′ may have an area that is greater than that of the first sub-pixel SP1′, and the third sub-pixel SP3′ may have an area that is greater than that of the second sub-pixel SP2′. Accordingly, the second emission area EMA2′ may have an area that is greater than the first emission area EMA1′, and the third emission area EMA3′ may have an area that is greater than that of the second emission area EMA2′. However, embodiments are not limited thereto. For example, the first and second sub-pixels SP1′ and SP2′ may have substantially the same area, and the third sub-pixel SP3′ may have an area greater than that of each of the first and second sub-pixels SP1′ and SP2′. As described above, the areas of the first to third sub-pixels SP1′, SP2′, and SP3′ may vary according to embodiments.

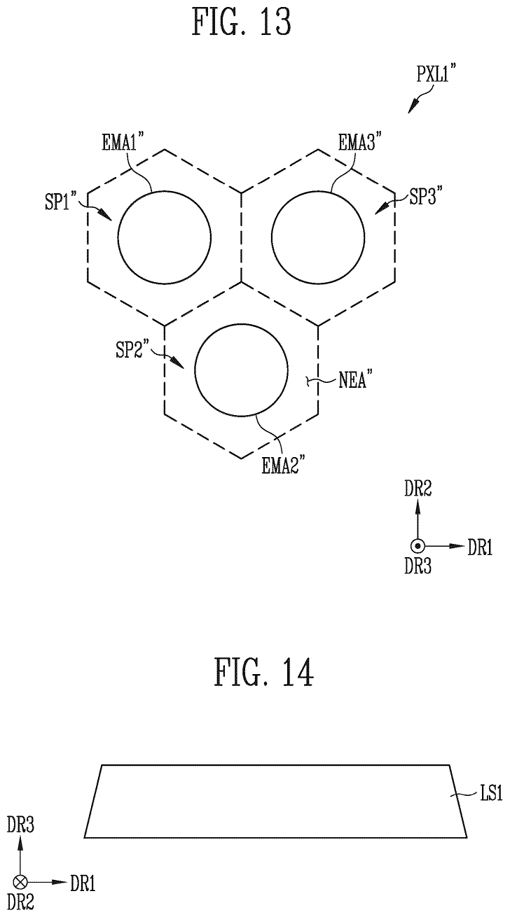

FIG. 13 is a plan view illustrating still one or more other embodiments of one of the pixels of FIG. 4.

Referring to FIG. 13, a first pixel PXL1″ may include first to third sub-pixels SP1″, SP2″, and SP3″. A first sub-pixel SP1″ may include a first emission area EMA1″, and a non-emission area NEA″ around the first emission area EMA1″. A second sub-pixel SP2″ may include a second emission area EMA2″, and a non-emission area NEA″ around the second emission area EMA2″. A third sub-pixel SP3″ may include a third emission area EMA3″, and a non-emission area NEA″ around the third emission area EMA3″.

The first to third sub-pixels SP1″, SP2″, and SP3″ may have polygonal shapes when viewed in the third direction DR3. For example, shapes of the first to third sub-pixels SP1″, SP2″, and SP3″ may be hexagonal shapes as shown in FIG. 13.

The first to third emission areas EMA1″, EMA2″, and EMA3″ may have circular shapes when viewed in the third direction DR3. However, embodiments are not limited thereto. For example, each of the first to third emission areas EMA1″ EMA2″, and EMA3″ may have a polygonal shape.

The first and third sub-pixels SP1″ and SP3″ may be arranged in the first direction DR1. The second sub-pixel SP2″ may be located in a direction inclined by an acute angle based on the second direction DR2 (or a diagonal direction) with respect to the first sub-pixel SP1″.

An arrangement of the sub-pixels shown in FIGS. 5, 12, and 13 is only an example, and embodiments are not limited thereto. Each pixel may include two or more sub-pixels SP, the sub-pixels SP may be arranged in various methods, the respective sub-pixels may have various shapes, and respective emission areas EMA1, EMA2, and EMA3 thereof may also have various shapes.

FIGS. 14 to 16 are cross-sectional views illustrating an example of a shape of the first lens of FIG. 6.

FIGS. 14 to 16 illustrate only the first lens LS1 for convenience of description, and the second and third lenses LS2 and LS3 (refer to FIG. 6) may also have substantially the same shape as the first lens LS1.

FIGS. 14 to 16 illustrate a cross-sectional shape of the first lens LS1 cut in the third direction DR3. The shape of the first lens LS1 viewed from the third direction DR3 may be substantially the same as the emission areas EMA1, EMA1′, EMA1″, EMA2, EMA2′, EMA2″, EMA3, EMA3′, and/or EMA3″ described with reference to FIGS. 5, 12, and 13.

Referring to FIG. 14, the first lens LS1 may have a trapezoidal shape. For example, a width of the first lens LS1 may become narrower in the third direction DR3.

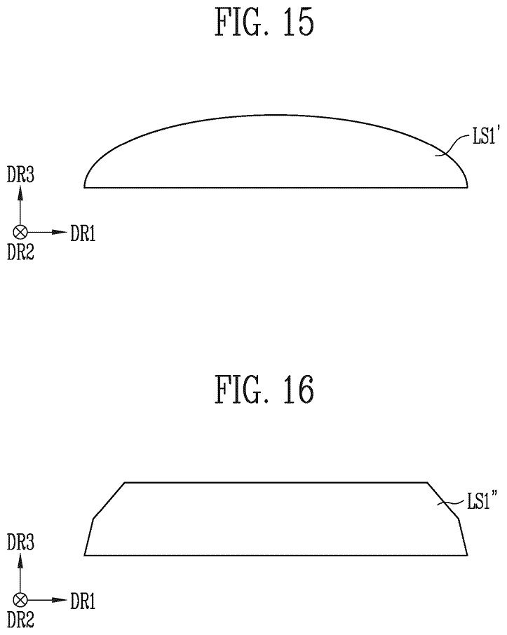

Referring to FIG. 15, a first lens LS1′ may have a semicircular shape. For example, the first lens LS1′ may have a shape of a lens convex in the third direction DR3.

Referring to FIG. 16, the first lens LS1″ may have a shape in which a corner is cut in a trapezoidal shape. For example, the corner of the first lens LS1″ may be cut so that a width of the first lens LS1″ becomes narrower in the third direction DR3 in the trapezoidal shape.

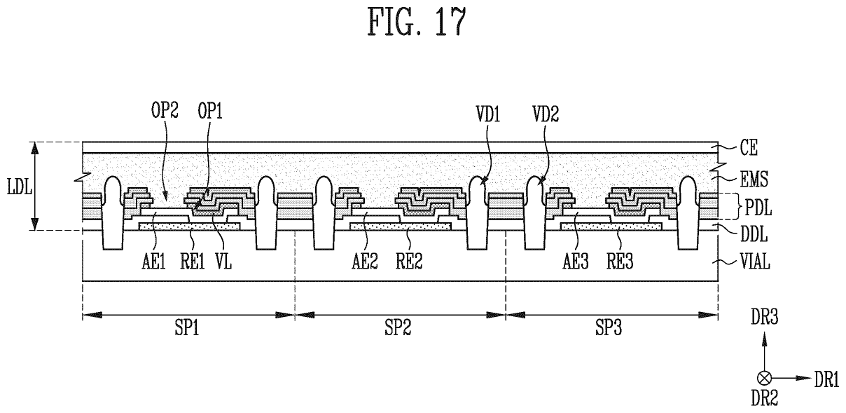

FIG. 17 is a cross-sectional view illustrating a portion of first to third sub-pixels of a display device according to embodiments of the disclosure.

For convenience of description, in FIG. 17, configurations other than the via layer VIAL, the first to third reflective electrodes RE1, RE2, and RE3, the differential layer DDL, the pixel-defining layer PDL, the first to third anode electrodes AE1, AE2, and AE3, a sacrificial layer VL, the light-emitting structure EMS, and the cathode electrode CE may be omitted.

Because the display device according to the present embodiments is substantially the same as the configuration of the display device of FIG. 6, except for the sacrificial layer VL, the same reference numerals and reference symbols are used for the same or similar components, and an overlapping description is not repeated.

Referring to FIG. 17, the display device may further include the sacrificial layer VL located between the first to third anode electrodes AE1, AE2, and AE3 and the pixel-defining layer PDL. The sacrificial layer VL may be located on the first to third anode electrodes AE1, AE2, and AE3 to protect the first to third anode electrodes AE1, AE2, and AE3. For example, when the sacrificial layer VL does not exist, the first to third anode electrodes AE1, AE2, and AE3 may be unintentionally etched during a process of etching the pixel-defining layer PDL. However, because the sacrificial layer VL is located, even though the pixel-defining layer PDL may be unintentionally over-etched during the process of etching the pixel-defining layer PDL, the sacrificial layer VL may be etched instead of the first to third anode electrodes AE1, AE2, and AE3.

The sacrificial layer VL may include at least one of conductive materials, such as indium tin oxide (ITO), indium zinc oxide (IZO), zinc oxide (ZnOₓ), indium gallium zinc oxide (IGZO), indium tin zinc oxide (ITZO), or aluminum (AI). For example, a thickness of the sacrificial layer VL may be about 150 Å to about 400 Å. However, a material of the sacrificial layer VL is not limited thereto.

In one or more embodiments, the sacrificial layer VL may have an under-cut structure between the first to third anode electrodes AE1, AE2, and AE3 and the pixel-defining layer PDL. For example, the sacrificial layer VL may have the under-cut structure recessed in the first direction DR1 or in a direction opposite to the first direction DR1 between the first to third anode electrodes AE1, AE2, and AE3 and the pixel-defining layer PDL.

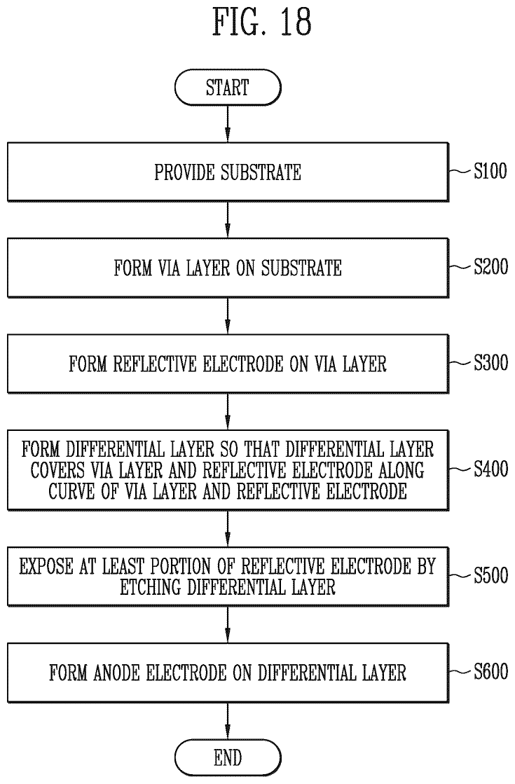

FIG. 18 is a flowchart illustrating a method of manufacturing a display device according to embodiments of the disclosure.

Referring to FIG. 18, the method of manufacturing the display device may provide a substrate (S100), may form a via layer on the substrate (S200), may form a reflective electrode on the via layer (S300), may form a differential layer so that the differential layer covers the via layer and the reflective electrode along a curve of the via layer and the reflective electrode (S400), may expose at least a portion of the reflective electrode by etching the differential layer (S500), and may form an anode electrode on the differential layer (S600).

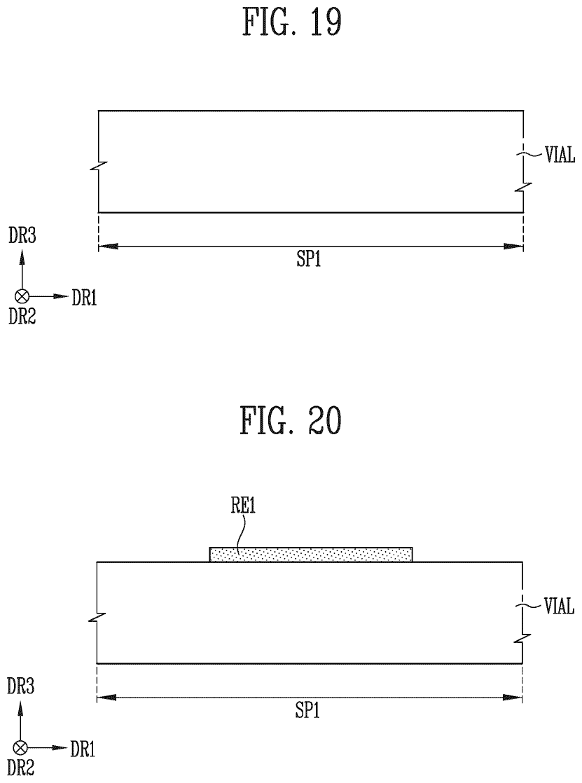

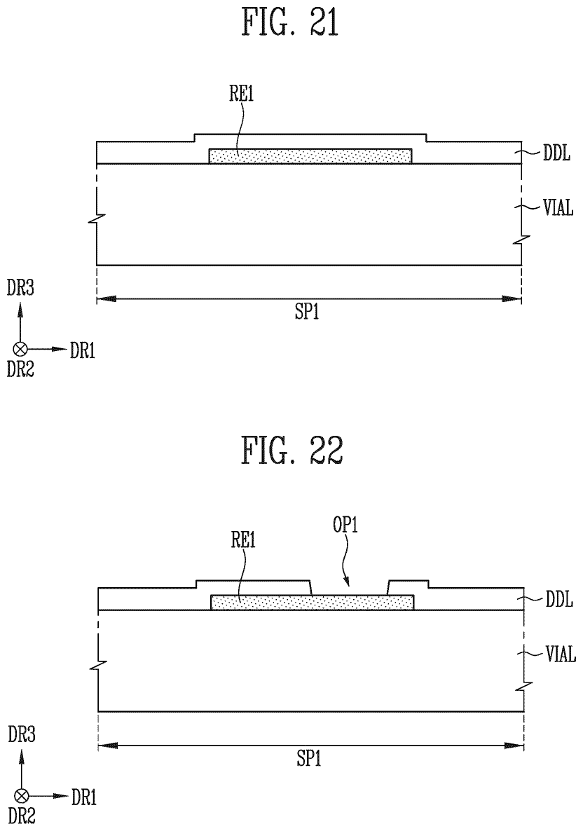

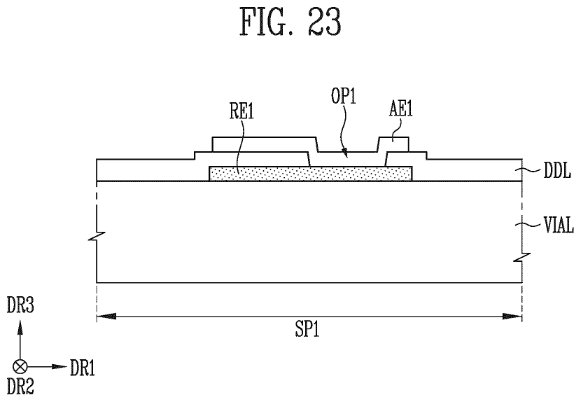

FIG. 19 is a diagram illustrating operation S200 of FIG. 18, FIG. 20 is a diagram illustrating operation S300 of FIG. 18, FIG. 21 is a diagram illustrating operation S400 of FIG. 18, FIG. 22 is a diagram illustrating operation S500 of FIG. 18, and FIG. 23 is a diagram illustrating operation S600 of FIG. 18.

FIGS. 19 to 23 illustrate only the first sub-pixel SP1 for convenience of description, and the second and third sub-pixels SP2 and SP3 (refer to FIG. 6) may also be manufactured in a method substantially equal to that of the first sub-pixel SP1.

Referring to FIG. 19, the method of manufacturing the display device may form the via layer VIAL on (e.g., above) the substrate. The via layer VIAL may be formed on the pixel circuit layer PCL (refer to FIG. 6). Because a detailed description of the via layer VIAL is described above, an overlapping description is omitted.

Referring to FIG. 20, the method of manufacturing the display device may form the first reflective electrode RE1 on the via layer VIAL. Because a detailed description of the reflective electrode including the first reflective electrode RE1 is described above, an overlapping description is omitted.

Referring to FIG. 21, the method of manufacturing the display device may form the differential layer DDL so that the differential layer DDL covers the via layer VIAL and the first reflective electrode RE1 along the curve of the via layer VIAL and the first reflective electrode RE1. That is, the differential layer DDL may be formed along the curve without a separate planarization process.

Referring to FIG. 22, the method of manufacturing the display device may expose at least a portion of the first reflective electrode RE1 by etching the differential layer DDL. That is, the differential layer DDL may include/define the first opening OP1 exposing at least a portion of the first reflective electrode RE1.

Referring to FIG. 23, the first anode electrode AE1 may be formed on the differential layer DDL. For example, the first anode electrode AE1 may be formed on at least a portion of an area overlapping the first reflective electrode RE1 of the differential layer DDL and the first opening OP1. Accordingly, the first anode electrode AE1 may directly contact the first reflective electrode RE1.

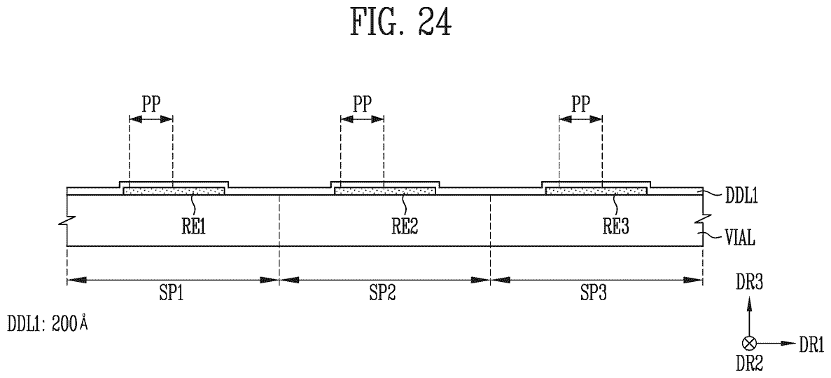

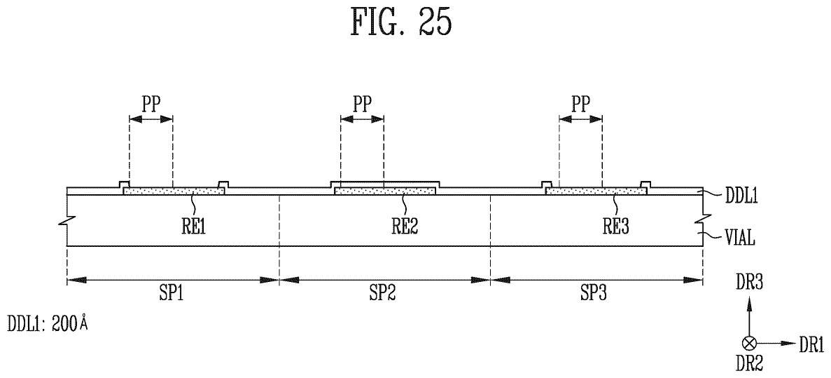

FIGS. 24 to 28 are diagrams illustrating a process in which a first differential layer and a second differential layer are formed according to a method of manufacturing a display device according to embodiments of the disclosure.

For convenience of description, FIGS. 24 to 28 illustrates the process in which the first differential layer DDL1 and the second differential layer DDL2 are formed according to CASE6 of FIG. 7.

Referring to FIGS. 24 to 28, the thickness of the differential layer (e.g., a sum of the thicknesses of the first and second differential layers DDL1 and DDL2) formed on the reflective electrode (e.g., the first to third reflective electrodes RE1, RE2, and RE3) may be different in at least two of the first to third sub-pixels SP1, SP2, and SP3.

Referring to FIGS. 24 and 25, the first differential layer DDL1 may be formed on the first to third reflective electrodes RE1, RE2, and RE3. In addition, the first differential layer DDL1 on the first reflective electrode RE1 and the third reflective electrode RE3 may be etched, and the portion PP of each of the first reflective electrode RE1 and the third reflective electrode RE3 may be exposed.

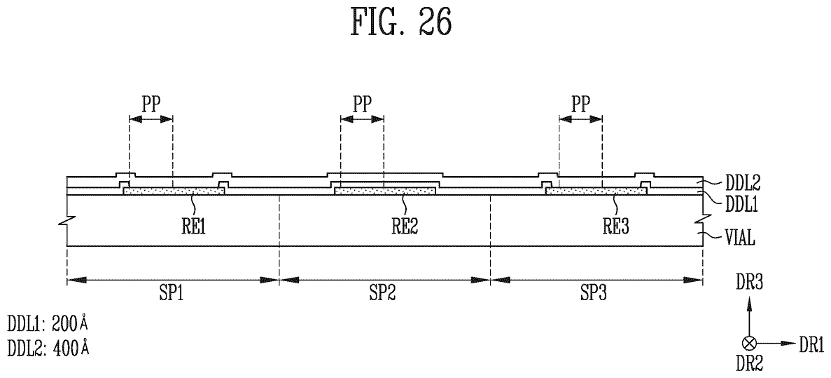

Referring to FIG. 26, the second differential layer DDL2 may be formed on the portion PP of each of the first reflective electrode RE1 and the third reflective electrode RE3. The second differential layer DDL2 may be formed on the first differential layer DDL1 formed on the second reflective electrode RE2.

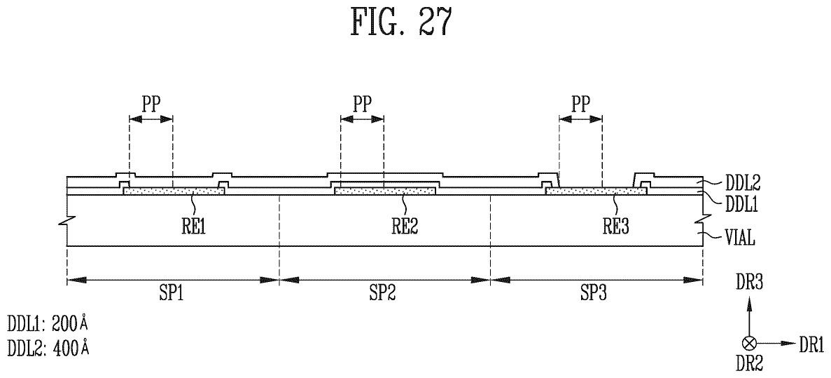

Referring to FIG. 27, the second differential layer DDL2 may be etched, and the portion PP of the third reflective electrode RE3 may be exposed. Accordingly, the thickness of the differential layer formed on the portion PP of the first reflective electrode RE1 may be about 400 Å, the thickness of the differential layer formed on the portion PP of the second reflective electrode RE2 may be about 600 Å, and the thickness of the differential layer formed on the portion PP of the reflective electrode RE3 may be about 0 Å.

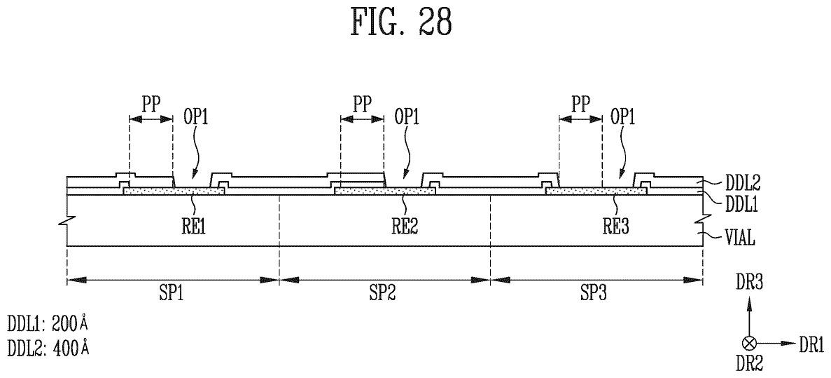

Referring to FIG. 28, the second differential layer DDL2 of the first sub-pixel SP1 may be etched, and the first opening OP1 exposing at least a portion of the first reflective electrode RE1 may be formed. The first differential layer DDL1 and the second differential layer DDL2 of the second sub-pixel SP2 may be etched, and the first opening OP1 exposing at least a portion of the second reflective electrode RE2 may be formed. The second differential layer DDL2 of the third sub-pixel SP3 may be etched, and the first opening OP1 exposing at least a portion of the third reflective electrode RE3 may be formed.

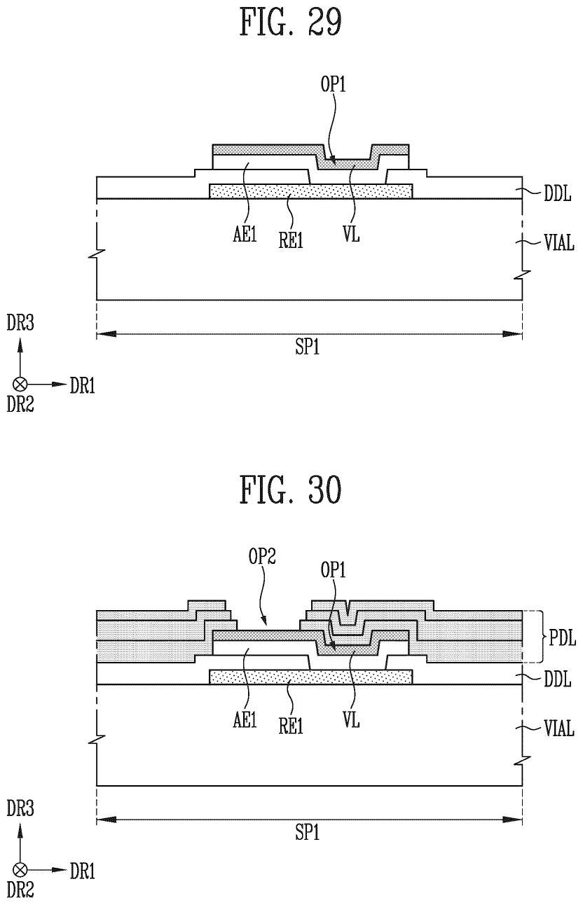

FIGS. 29 to 31 are diagrams illustrating a process in which a sacrificial layer is formed according to a method of manufacturing a display device according to embodiments of the disclosure.

Because the display device according to the present embodiments is substantially the same as the configuration of the method of manufacturing the display device of FIG. 18, except for the sacrificial layer VL, the same reference numerals and reference symbols are used for the same or similar components, and an overlapping description is omitted.

FIGS. 29 to 31 illustrate only the first sub-pixel SP1 for convenience of description, and the second and third sub-pixels SP2 and SP3 (refer to FIG. 6) may also be manufactured in a method substantially equal to that of the first sub-pixel SP1.

Referring to FIG. 29, the sacrificial layer VL may be formed on the first anode electrode AE1. Because a detailed description of the sacrificial layer VL is described above, an overlapping description is omitted.

Referring to FIG. 30, the pixel-defining layer PDL including/defining the second opening OP2 for exposing at least a portion of the sacrificial layer VL may be formed on/above the sacrificial layer VL. Because a detailed description of the pixel-defining layer PDL is described above, an overlapping description is omitted.

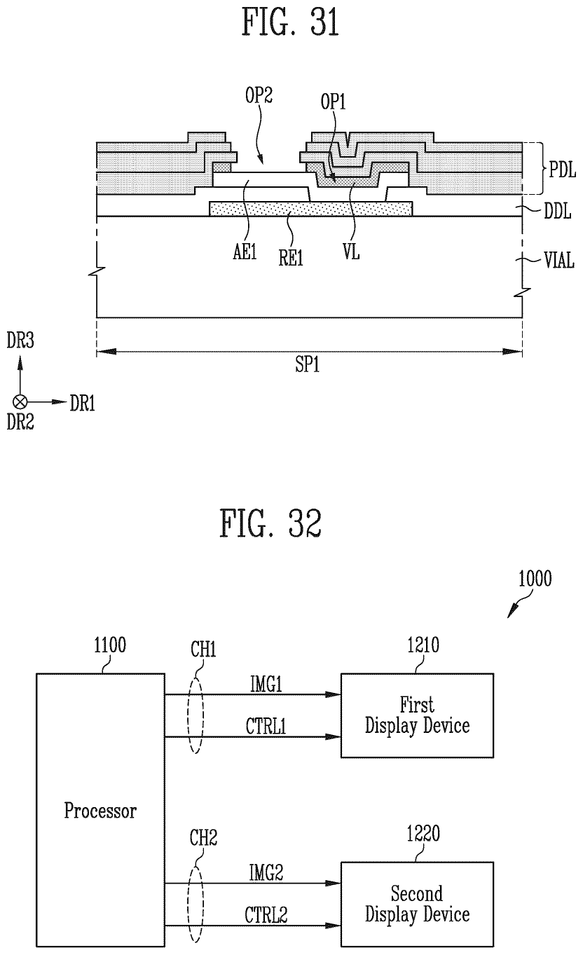

Referring to FIG. 31, the sacrificial layer VL may be etched, and at least a portion of the first anode electrode AE1 may be exposed. For example, the sacrificial layer VL may be wet etched. Accordingly, the sacrificial layer VL may have an under-cut structure between the first anode electrode AE1 and the pixel-defining layer PDL.

FIG. 32 is a block diagram illustrating one or more embodiments of a display system.

Referring to FIG. 32, the display system 1000 may include a processor 1100 and one or more display devices 1210 and 1220.

The processor 1100 may perform various tasks and calculations. In embodiments, the processor 1100 may include an application processor, a graphic processor, a microprocessor, a central processing unit (CPU), and the like. The processor 1100 may be connected to other components of the display system 1000 through a bus system and may control the other components.

In FIG. 32, the display system 1000 includes the first and second display devices 1210 and 1220. The processor 1100 may be connected to the first display device 1210 through a first channel CH1, and may be connected to the second display device 1220 through a second channel CH2.

Through the first channel CH1, the processor 1100 may transmit first image data IMG1 and a first control signal CTRL1 to the first display device 1210. The first display device 1210 may display an image based on the first image data IMG1 and the first control signal CTRL1. The first display device 1210 may be configured similarly to the display device 100 described with reference to FIG. 1. In this case, the first image data IMG1 and the first control signal CTRL1 may be provided as the input image data IMG and the control signal CTRL of FIG. 1, respectively.

Through the second channel CH2, the processor 1100 may transmit second image data IMG2 and a second control signal CTRL2 to the second display device 1220. The second display device 1220 may display an image based on the second image data IMG2 and the second control signal CTRL2. The second display device 1220 may be configured similarly to the display device 100 described with reference to FIG. 1. In this case, the second image data IMG2 and the second control signal CTRL2 may be provided as the input image data IMG and the control signal CTRL of FIG. 1, respectively.

The display system 1000 may include a computing system for providing an image display function, such as a portable computer, a mobile phone, a smart phone, a tablet personal computer (PC), a smart watch, a watch phone, a portable multimedia player (PMP), a navigation device, and an ultra-mobile personal computer (UMPC). In addition, the display system 1000 may include at least one of a head-mounted display (HMD) device, a virtual reality (VR) device, a mixed reality (MR) device, or an augmented reality (AR) device.

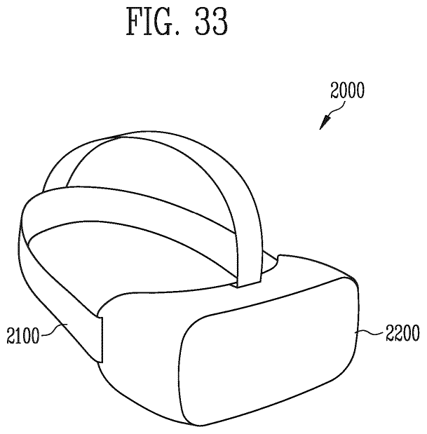

FIG. 33 is a perspective view illustrating an application example of the display system of FIG. 32.

Referring to FIG. 33, the display system 1000 of FIG. 32 may be applied to a head-mounted display device 2000. The head-mounted display device 2000 may be a wearable electronic device that may be worn on a user's head.

The head-mounted display device 2000 may include a head mount band 2100 and a display device accommodation case 2200. The head mount band 2100 may be connected to the display device accommodation case 2200. The head mount band 2100 may include a horizontal band and/or a vertical band for fixing the head-mounted display device 2000 to the user's head. The horizontal band may be configured to surround a side portion of the user's head, and the vertical band may be configured to surround an upper portion of the user's head. However, embodiments are not limited thereto. For example, the head mount band 2100 may be implemented in a glasses frame form, a helmet form, or the like.

The display device accommodation case 2200 may accommodate the first and second display devices 1210 and 1220 of FIG. 32. The display device accommodation case 2200 may further accommodate the processor 1100 of FIG. 32.

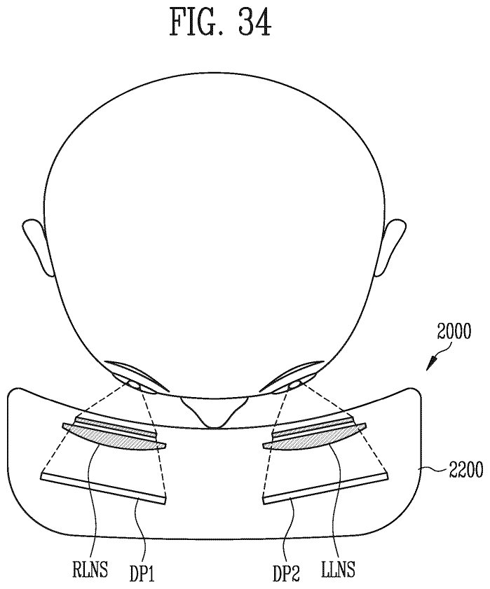

FIG. 34 is a diagram illustrating the head-mounted display device worn by a user of FIG. 33.

Referring to FIG. 34, in a head-mounted display device 2000, a first display panel DP1 of the first display device 1210 and a second display panel DP2 of the second display device 1220 are located. The head-mounted display device 2000 may further include one or more lenses LLNS and RLNS.

Within the display device accommodation case 2200, the right eye lens RLNS may be located between the first display panel DP1 and a user's right eye. Within the display device accommodation case 2200, the left eye lens LLNS may be located between the second display panel DP2 and a user's left eye.

An image output from the first display panel DP1 may be displayed to the user's right eye through the right eye lens RLNS. The right eye lens RLNS may refract light from the first display panel DP1 to be directed toward the user's right eye. The right eye lens RLNS may perform an optical function for adjusting a viewing distance between the first display panel DP1 and the user's right eye.

An image output from the second display panel DP2 may be displayed to the user's left eye through the left eye lens LLNS. The left eye lens LLNS may refract light from the second display panel DP2 to be directed toward the user's left eye. The left eye lens LLNS may perform an optical function for adjusting a viewing distance between the second display panel DP2 and the user's left eye.

In embodiments, each of the right eye lens RLNS and the left eye lens LLNS may include an optical lens having a pancake-shaped cross-section. In embodiments, each of the right eye lens RLNS and the left eye lens LLNS may include a multi-channel lens including sub-areas having different optical characteristics. In this case, each display panel may output images respectively corresponding to the sub-areas of the multi-channel lens, and the output images may pass through the respective corresponding sub-areas and may be viewed to the user.

Although various embodiments and application examples are described herein, they are provided only to facilitate a more general understanding of the disclosure, the disclosure is not limited to the above-described embodiments, and various modifications and variations are possible from this description by those of ordinary skill in the field to which the disclosure pertains.

Therefore, the spirit of the disclosure should not be limited to the described embodiments, and the scope of the patent claims described below as well as all modifications that are equivalent or equivalent to the scope of this patent claim may fall within the scope of the spirit of the disclosure.

The disclosure may be applied to a display device and an electronic device including the display device. For example, the disclosure may be applied to a digital TV, a 3D TV, a mobile phone, a smart phone, a tablet computer, a VR device, a PC, a home electronic device, a notebook computer, a PDA, a PMP, a digital camera, a music player, a portable game console, a navigation system, and the like.

Although described with reference to the above embodiments, it will be understood that those skilled in the art can variously modify and change the disclosure without departing from the spirit and scope of the disclosure described in the claims below, with functional equivalents thereof to be included therein.

What is claimed is:

1. A display device comprising:
a substrate;
a first insulating layer above the substrate;
a first electrode above the first insulating layer;
a second insulating layer above the first insulating layer and the first electrode along a curve of the first insulating layer and the first electrode;
a second electrode above the second insulating layer;
a light-emitting structure above the second electrode; and
a third electrode above the light-emitting structure.

2. The display device according to claim 1, wherein the second insulating layer defines a first opening exposing at least a portion of the first electrode, and
wherein the second electrode directly contacts the first electrode.

3. The display device according to claim 2, further comprising a third insulating layer defining a second opening exposing at least a portion of the second electrode,
wherein the third insulating layer is above an area of the second electrode that directly contacts the first electrode.

4. The display device according to claim 1, wherein the substrate comprises a display area where first, second, and third sub-pixels are located, and
wherein respective thicknesses of the second insulating layer above respective portions of the first electrode in at least two of the first, second, or third sub-pixels are different.

5. The display device according to claim 4, wherein the second insulating layer comprises a (2-1)-th insulating layer and a (2-2)-th insulating layer, and
wherein a portion of the (2-1)-th insulating layer or a portion of the (2-2)-th insulating layer is omitted above a portion of the first electrode.

6. The display device according to claim 1, further comprising:
a third insulating layer defining a second opening exposing at least a portion of the second electrode; and
a sacrificial layer between the second electrode and the third insulating layer.

7. The display device according to claim 6, wherein the sacrificial layer comprises a conductive material.

8. The display device according to claim 6, wherein the sacrificial layer has an under-cut structure between the second electrode and the third insulating layer.

9. The display device according to claim 1, wherein the light-emitting structure is configured to output white light.

10. A display device comprising:
a substrate;
a first insulating layer above the substrate;
a first electrode above the first insulating layer;
a second insulating layer above the first insulating layer and the first electrode, and directly contacting the first electrode;
a second electrode above the second insulating layer;
a light-emitting structure above the second electrode; and
a third electrode above the light-emitting structure.

11. The display device according to claim 10, further comprising a third insulating layer defining a second opening exposing at least a portion of the second electrode,
wherein the third insulating layer is above an area of the second electrode that directly contacts the first electrode.

12. The display device according to claim 10, wherein the substrate comprises a display area where first, second, and third sub-pixels are located, and
wherein respective thicknesses of the second insulating layer above respective portions of the first electrode in at least two of the first, second, or third sub-pixels are different.

13. The display device according to claim 12, wherein the second insulating layer comprises a (2-1)-th insulating layer and a (2-2)-th insulating layer, and
wherein a portion of the (2-1)-th insulating layer or a portion of the (2-2)-th insulating layer is omitted above a portion of the first electrode.

14. The display device according to claim 10, further comprising:
a third insulating layer defining a second opening exposing at least a portion of the second electrode; and
a sacrificial layer between the second electrode and the third insulating layer.

15. The display device according to claim 14, wherein the sacrificial layer comprises a conductive material.

16. The display device according to claim 14, wherein the sacrificial layer has an under-cut structure between the second electrode and the third insulating layer.

17. The display device according to claim 10, wherein the light-emitting structure is configured to output white light.
